(19) United States
(12) Patent Application Publication
(10) Pub. No.: US 2013/0187103 A1
(43) Pub. Date: Jul. 25, 2013

(54) MATERIALS FOR ORGANIC ELECTROLUMINESCENT DEVICES

(71) Applicants: Susanne Heun, Bad Soden (DE); Aurélie Ludemann, Frankfurt am Main (DE); Rémi Manouk Anémian, Seoul (KR)

(72) Inventors: Susanne Heun, Bad Soden (DE); Aurélie Ludemann, Frankfurt am Main (DE); Rémi Manouk Anémian, Seoul (KR)

(73) Assignee: Merck Patent GmbH, Darmstadt (DE)

(21) Appl. No.: 13/823,313

(22) PCT Filed: Aug. 16, 2011
(86) PCT No.: PCT/EP2011/004105

§ 371 Date: Apr. 3, 2013

(30) Foreign Application Priority Data
Sep. 14, 2010 (DE) 10 2010 045 369.2

(51) Int. Cl. H01L 51/00

(52) U.S. Cl. CPC H01L 51/0039
USPC 252/519.21; 528/8; 546/4

(57) ABSTRACT

The present invention relates to electroluminescent polymers which contain at least one structural unit which includes at least one phosphorescent emitter unit, to processes for the preparation of these polymers, to mixtures (also called blends), solutions and formulations which comprise these polymers, to the use of these polymers in electronic devices, in particular in organic electro-luminescent devices, so-called OLEDs (OLED=organic light emitting diodes), and to electronic devices containing these polymers. The polymers according to the invention exhibit improved efficiency and a longer lifetime, in particular on use in OLEDs.

### CROSS-REFERENCE TO RELATED APPLICATIONS

This application is a national stage application (under 35 U.S.C. §371) of PCT/EP2011/004105, filed Aug. 16, 2011, which claims benefit of German Application 10 2010 045 369.2, filed Sep. 14, 2010.

### BACKGROUND OF THE INVENTION

The present invention relates to electroluminescent polymers which contain at least one structural unit which includes at least one phosphorescent emitter unit, to processes for the preparation of these polymers, to mixtures (also called blends), solutions and formulations which comprise these polymers, to the use of these polymers in electronic devices, in particular in organic electroluminescent devices, so-called OLEDs (OLED=organic light emitting diodes), and to electronic devices containing these polymers. The polymers according to the invention exhibit improved efficiency and a longer lifetime, in particular on use in OLEDs.

Polymers for opto-electronic applications are preferably either conjugated or partially conjugated main-chain polymers, in which the polymer backbone itself plays an important role with respect to the opto-electronic properties, side-chain polymers, whose functionality is achieved by a transport unit which is chemically bonded to the backbone, or neutral polymers, which are only responsible for the film-forming properties (known of organic photoreceptors, in which the hole-transport materials are typically mixed into polycarbonate).

Conjugated polymers have already been investigated intensively for a long time as highly promising materials in OLEDs. OLEDs which contain polymers as organic materials are frequently also called PLEDs (PLED=polymeric light emitting diodes). Their simple production promises inexpensive production of corresponding electroluminescent devices.

Since PLEDs usually consist only of a light-emitting layer, polymers are required which are able to combine as far as possible all functions (charge injection, charge transport, recombination) of an OLED in themselves. In order to meet these requirements, different monomers which take on the corresponding functions are employed during the polymerisation. Thus, it is generally necessary, for the generation of all three emission colours, to copolymerise certain comonomers into the corresponding polymers (cf., for example, WO 00/046321 A1, WO 03/020790 A2 and WO 02/077060 A1). Thus, it is possible, for example starting from a blue-emitting base polymer (“backbone”), to generate the other two primary colours red and green.

As polymers for full-colour display elements, various classes of material, such as, for example, poly-para-phenylenes (PPPs), have already been proposed or developed. Thus, for example, polyfluorene, polyspirobifluorene, polyphenanthrene, polydihydrophenanthrene and polyindenofluorene derivatives come into consideration. Polymers which contain a combination of the said structural elements have also already been proposed.

The most important criteria of an OLED are efficiency, colour and lifetime. Since these properties are crucially determined by the emitter(s) used, improvements to the emitters compared with the materials known from the prior art continue to be required.

In order to provide a system having a long lifetime and adequate efficiency, predominantly conjugated polymers have been used to date. However, conjugated polymers used and disclosed to date have the disadvantage that the achievable efficiency has a certain upper limit, since conjugated polymers are generally singlet emitters, which have a limited lightemission efficiency.

Phosphorescent emitters generally have higher efficiency than singlet emitters. However, the incorporation of phosphorescent emitters into the polymer backbone has hitherto only been possible for phosphorescent emitters in the deep-red region, since the conjugated backbone and/or the additional transport units quench the emission of any phosphorescent emitters having relatively high energy (relatively short wavelengths). With the exception of phosphorescent emitter polymers which emit in the deep-red region, it has to date not been possible to provide any polymers having a very long lifetime and high emission efficiency.

Although it is possible, in order to circumvent the above-mentioned problem of “quenching”, to avoid conjugation in the polymer backbone, the lifetime of such polymers is, however, not comparable with that of conjugated polymers which emit in the blue or green region. Thus, for example, poly-N-vinylcarbazole is a known system for a phosphorescent emitter in the green region, but opto-electronic devices produced therefrom have extremely short lifetimes, like all polymers known at present which contain a phosphorescent emitter in the side chain.

The problem to be solved was thus to combine the advantages of the conjugated polymers and the phosphorescent emitters with one another in one system. In other words, the aim was to provide conjugated polymers which have the high emission efficiency of phosphorescent emitters, without reducing the light yield due to the occurrence of “quenching”.

One of the objects of the present invention was therefore to provide electroluminescent polymers which have improved efficiency and a relatively long lifetime and in particular also facilitate blue and green emission colour in the polymer.

This object has been achieved in accordance with the invention by the provision of a polymer which contains at least one structural unit of the following formula (I):

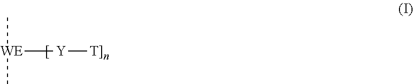

where the symbols and indices used have the following meanings:
WE represents the recurring unit in the polymer,
Y represents a single covalent bond or a conjugation-interrupting unit;
T is a phosphorescent emitter unit;
n is 1, 2, 3 or 4, preferably 1 or 2 and particularly preferably 1;
and the dashed lines represent the linking in the polymer.

### A BRIEF DESCRIPTION OF THE FIGURES

FIG. 1 illustrates the structure of the typical device.

FIG. 2 illustrates the diagram on the left: ITO structure applied to the glass support, diagram on the right: complete electronic structure with ITO, vapour-deposited cathode and optional metallisation of the leads.

FIG. 3 illustrates the typical measurement set-up.

### A DETAILED DESCRIPTION OF THE INVENTION

The recurring unit WE here is preferably selected from the following recurring units of the formulae (WEa) to (WEn)

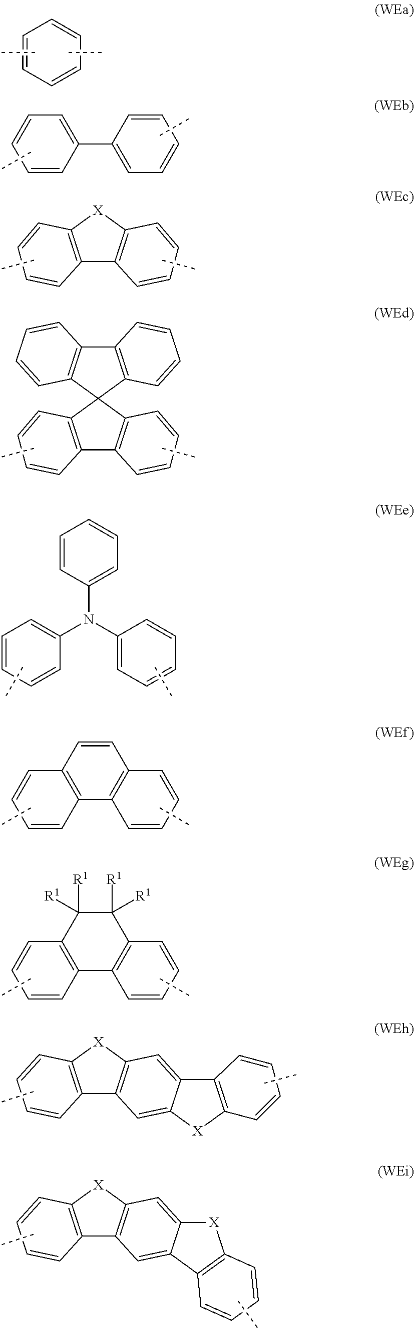

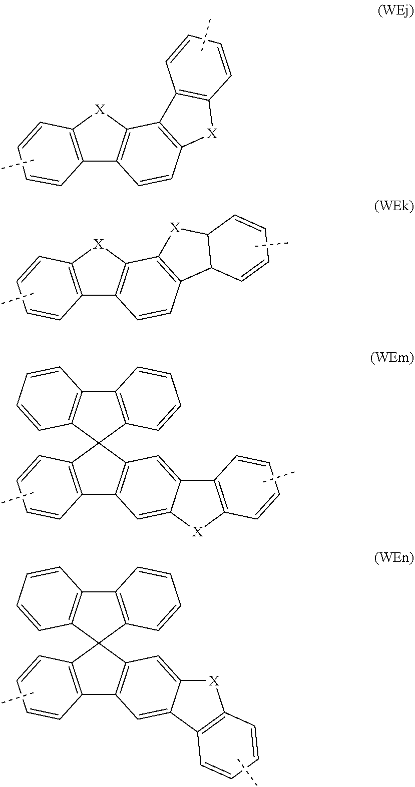

where X is in each case, independently of one another, identically or differently, C(R¹)₂, NR¹, O or S, and
one or more H atoms on the phenyl rings of the recurring units (WEa) to (WEn) may each be replaced by a radical R¹.

X in the formulae (WEc), (WEm) and (WEn) is preferably C(R¹)₂ or NR¹, particularly preferably C(R¹)₂. In the formulae (WEh), (WEi), (WEj) and (WEk), it is preferred for both X to be C(R¹)₂, for both X to be NR¹ or for one X to be C(R¹)₂ and the other X to be NR¹. Particularly preferably, both X are C(R¹)₂.

The radicals R¹ here are, independently of one another, identically or differently, H, F, Cl, Br, I, N(Ar¹)₂, C(═O)Ar¹, P(═O)Ar¹₂, S(═O)Ar¹, S(═O)₂Ar¹, CR²═CR²Ar¹, CN, NO₂, Si(R²)₃, B(OR²)₂, OSO₂R², a straight-chain alkyl, alkoxy or thioalkoxy group having 1 to 40 C atoms, a branched or cyclic alkyl, alkoxy or thioalkoxy group having 3 to 40 C atoms, each of which may be substituted by one or more radicals R², where one or more non-adjacent CH₂ groups may be replaced by R²C═CR², C≡C, Si(R²)₂, Ge(R²)₂, Sn(R²)₂, C═O, C═S, C═NR², P(═O)(R²), SO, SO₂, NR², O, S or CONR² and where one or more H atoms may be replaced by F, Cl, Br, I, CN or NO₂, an aryl, aryloxy, heteroaryl or heteroaryloxy group having 5 to 40 C atoms, which may also be substituted by one or more non-aromatic radicals R¹, where two or more radicals R¹, preferably two adjacent radicals R¹, may also form an aliphatic or aromatic, mono- or polycyclic ring system with one another.

Ar¹ is selected on each occurrence, in each case independently of one another, from an aryl or heteroaryl group or an aromatic or heteroaromatic ring system.

R² is in each case, independently of one another, H, an aliphatic hydrocarbon radical having 1 to 20 C atoms or an aromatic hydrocarbon radical having 6 to 20 C atoms, where two or more radicals R² may also form a ring system with one another.

The aromatic ring system in the sense of the present invention preferably contains 6 to 60 C atoms in the ring system. The heteroaromatic ring system in the sense of the present invention contains 2 to 60 C atoms and at least one heteroatom in the ring system, with the proviso that the sum of C atoms and heteroatoms is at least 5. The heteroatoms are preferably selected from Si, N, P, O, S and/or Se, particularly preferably selected from N, P, O and/or S. An aromatic or heteroaromatic ring system in the sense of the present invention is, in addition, intended to be taken to mean a system which does not necessarily contain only aryl or heteroaryl groups, but instead in which a plurality of aryl or heteroaryl groups may also be interrupted by a non-aromatic unit (preferably less than 10% of the atoms other than H), such as, for example, a C (sp³-hybridised), N or O atom. Thus, for example, systems such as, for example, 9,9′-spirobifluorene, 9,9-diaryifluorene, triarylamine, diaryl ethers and stilbene are also intended to be taken to be aromatic ring systems in the sense of the present invention, as are systems in which two or more aryl groups are interrupted, for example, by a linear or cyclic alkyl group or by a silyl group. P═O or C═O groups are usually not conjugation-interrupting.

Aromatic groups may be monocyclic or polycyclic, i.e. they may have one ring (for example phenyl) or two or more rings, which may also be condensed (for example naphthyl) or covalently linked (for example biphenyl), or contain a combination of condensed and linked rings. Fully conjugated aromatic groups are preferred.

An aromatic or heteroaromatic ring system having 5 to 60 ring atoms, which may also in each case be substituted by any desired radicals R and linked to the aromatic or heteroaromatic ring system via any desired positions, is taken to mean, in particular, groups derived from phenyl, naphthyl, anthracene, phenanthrene, pyrene, chrysene, perylene, fluoranthene, naphthacene, tetracene, pentacene, benzopyrene, biphenyl, biphenylene, binaphthyl, terphenyl, terphenylene, fluorene, spirobifluorene, dihydrophenanthrene, dihydropyrene, tetrahydropyrene, cis- or trans-indenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine, benzothiadiazoie, benzanthrene, benzanthracene, rubicene and triphenylene.

The aromatic or heteroaromatic ring system is particularly preferably phenyl, biphenyl, terphenyl, naphthyl, anthracene, binaphthyl, phenanthrene, dihydrophenanthrene, pyrene, dihydropyrene, chrysene, perylene, tetracene, pentacene, benzopyrene, fluorene, indene, indenofluorene and spirobifluorene.

An aryl group in the sense of the present invention contains 6 to 60 C atoms. A heteroaryl group in the sense of the present invention contains 2 to 60 C atoms and at least one heteroatom, with the proviso that the sum of C atoms and heteroatoms is at least 5. The heteroatoms are preferably selected from Si, N, P, O, S and/or Se; particularly preferably selected from N, P, O or S. An aryl group or heteroaryl group here is taken to mean either a simple aromatic ring, i.e. benzene, or a simple heteroaromatic ring, for example pyridine, pyrimidine or thiophene, or a condensed aryl or heteroaryl group, for example naphthalene, anthracene, phenanthrene, quinoline, isoquinoline, benzothiophene, benzofuran and indole.

In the present invention, the term “aliphatic hydrocarbon radical having 1 to 20 carbon atoms” is taken to mean a saturated or unsaturated, non-aromatic hydrocarbon radical, which may be linear, branched or cyclic (alkyl group). One or more carbon atoms may be replaced by 0 (alkoxy group), N or S (thioalkoxy group). In addition, one or more hydrogen atoms may be replaced by fluorine. Examples of such compounds include the following: methyl, ethyl, n-propyl, i-propyl, n-butyl, i-butyl, s-butyl, t-butyl, 2-methylbutyl, n-pentyl, s-pentyl, cyclopentyl, n-hexyl, cyclohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, octynyl, methoxy, trifluoromethoxy, ethoxy, n-propoxy, i-propoxy, n-butoxy, i-butoxy, s-butoxy, t-butoxy and 2-methylbutoxy, where methyl, ethyl, i-propyl and i-butyl are particularly preferred.

In the structural unit of the formula (I), Y represents a single covalent bond or a conjugation-interrupting unit.

The fact that the conjugated system of the backbone from which the polymer is at least partly built up and the phosphorescent emitter unit are separated from one another by a conjugation-interrupting unit has the advantage that the overlap integral between backbone and the phosphorescent emitter unit, and thus also the undesired effect of “quenching”, is kept as small as possible. A high emission efficiency of the phosphorescent emitter unit is thus guaranteed.

A conjugation-interrupting unit in the present application is taken to mean a unit which interferes with or preferably interrupts the conjugation, i.e. a possible conjugation between the units linked to the conjugation-interrupting unit is interfered with or preferably interrupted. Conjugation in chemistry is taken to mean the overlap of a π orbital with a p orbital of an sp²-hybridised (carbon) atom or further π orbitals. By contrast, a conjugation-interrupting unit in the sense of the present application is taken to mean a unit which interferes with or preferably completely prevents such an overlap. This can occur, for example, by means of a unit in which the conjugation is interfered with by at least one sp³-hybridised atom, preferably carbon. The conjugation can likewise be interfered with by a non-sp³-hybridised atom, for example by N, P or Si. It is particularly preferred in accordance with the invention for the polymer to be a non-conjugated polymer.

It is particularly preferred in accordance with the invention for the conjugation-interrupting unit Y to contain an sp³-hybridised atom.

According to a preferred embodiment, Y in the structural unit of the formula (I) is preferably a linear or branched alkylene group having 1 to 20 C atoms, particularly preferably having 1 to 12 C atoms, in which one or more non-adjacent CH₂ groups may be replaced by —O—, —S—, —NH—, —N(CH₃)—, —N—CO—, —N—CO—O—, —N—CO—N, —CO—, —O—CO—, —S—CO—, —O—COO—, —CO—S—, —CO—O—, —CH(halogen)-, —CH(CN)—, —CH═CH— or —C≡C—, or a cyclic alkyl group, preferably cyclohexane or a cyclohexane derivative having 1,4- or 1,3-linking. Further possible spacer groups Y are, for example, —(CH₂)ₒ—, —(CH₂CH₂O)ₚ—CH₂CH₂—, —CH₂CH₂—S—CH₂CH₂— or —CH₂CH₂—NH—CH₂CH₂—, where o=1 to 12, preferably 2 to 12, and p=1 to 3, but also —O—.

Particularly preferred conjugation-interrupting units Y are methylene, ethylene, propylene, butylene, pentylene, hexylene, heptylene, octylene, nonylene, decylene, undecylene, dodecylene, octadecylene, ethyleneoxy-ethylene, methyleneoxybutylene, ethylenethioethylene, ethylene-N-methyl-iminoethylene, 1-methylalkylene, ethenylene, propenylene and butenylene.

It is particularly preferred for Y to denote an alkylene or alkyleneoxy group having 2 to 8 C atoms. Straight-chain groups are particularly preferred here.

In a further preferred embodiment, Y in the structural unit of the formula (I) conforms to the following formula (III)

—Ar²-X— (III)

where
Ar^{e} is selected on each occurrence, in each case independently of one another, from an aryl or heteroaryl group or an aromatic or heteroaromatic ring system; and
X is a conjugation-interrupting group, which can adopt the meanings of Y indicated above in relation to the structural unit of the formula (I).

In a further preferred embodiment, Y in the structural unit of the formula (I) corresponds to an ortho- or meta-linked phenyl group.

One representative of Ar² and X here is bonded to the recurring unit WE of the structural unit of the formula (I) and the other representative is bonded to the phosphorescent emitter unit T. Preferably, Ar² is bonded to the recurring unit WE of the structural unit of the formula (I) and X is bonded to the phosphorescent emitter unit T.

The structural unit of the formula (I) is particularly preferably selected from the following structural units of the formulae (Ia) to (In)

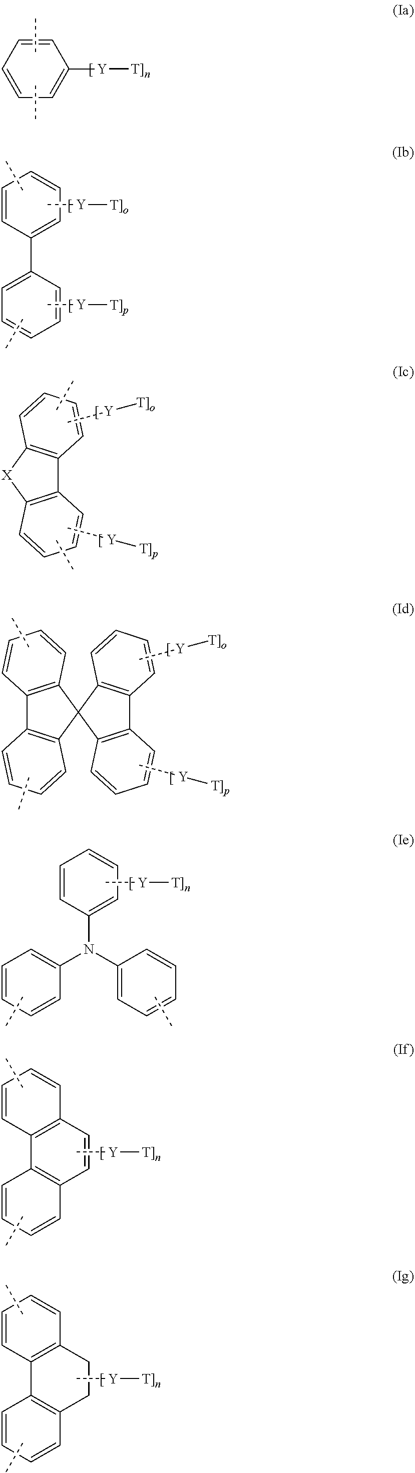

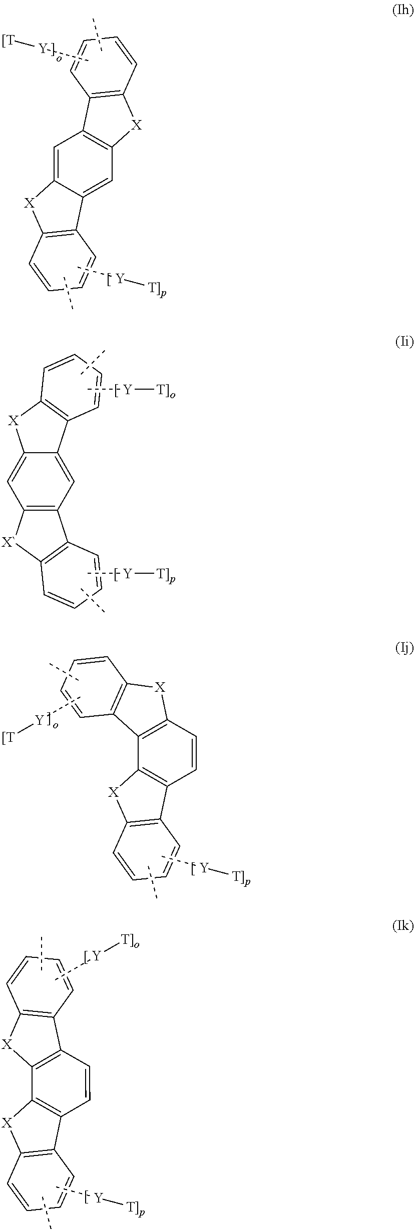

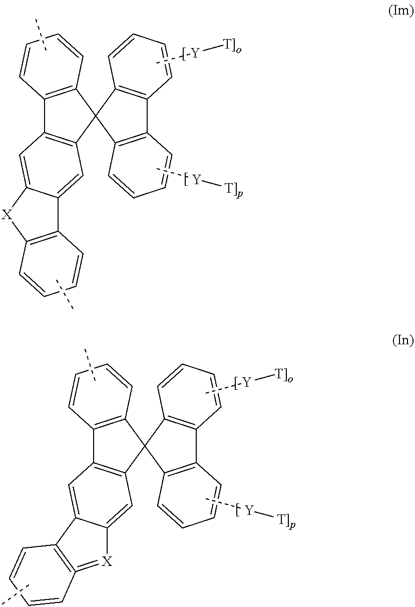

where
one or more H atoms on the phenyl rings of the structural units (Ia) to (In) may each be replaced by a radical R¹;
n is 1, 2, 3 or 4, preferably 1 or 2 and particularly preferably 1,
o and p each, independently of one another, identically or differently,
denote 0, 1 or 2, where the sum (o+p)=n and n has the meaning indicated above,
Y and T have the meanings indicated above in relation to the structural unit of the formula (I);
X has the meanings indicated above in relation to the recurring units (WEa) to (WEn), where this also applies to the preferred and particularly preferred meanings; and
R¹ has the meaning indicated above in relation to the recurring units (WEa) to (WEn), and may be —Y-T.

The structural unit of the formula (I) is very particularly preferably selected from the following structural units of the formulae (Ia1) to (In1)

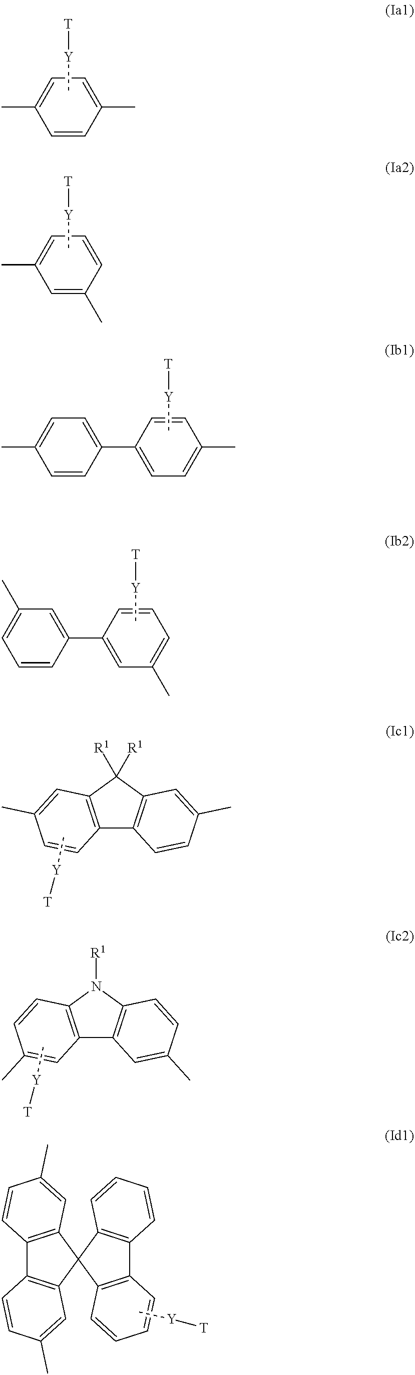

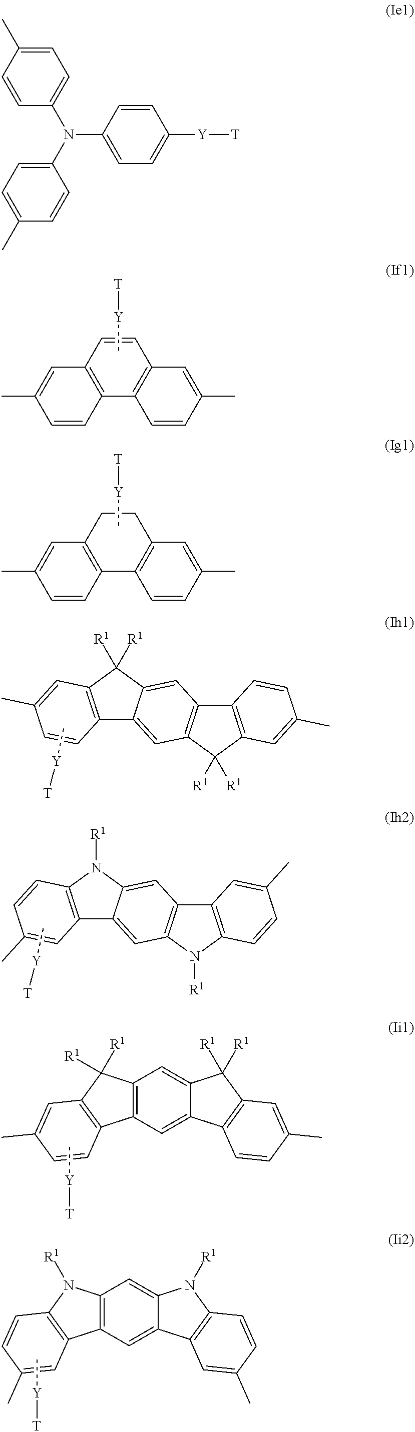

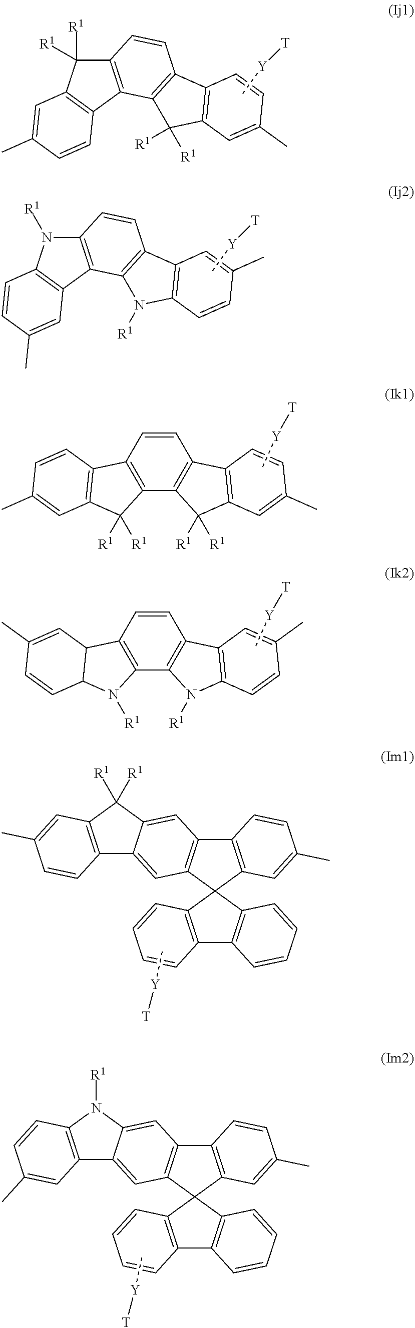

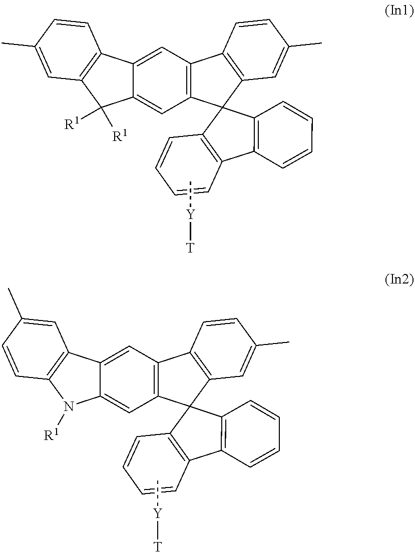

where
one or more H atoms on the phenyl rings of the structural units (Ia1) to (IM) may each be replaced by a radical R¹;
Y and T have the meanings indicated above in relation to the structural unit of the formula (I);
X has the meanings indicated above in relation to the recurring units (WEa) to (WEn), where this also applies to the preferred and particularly preferred meanings; and
R¹ has the meaning indicated above in relation to the recurring units (WEa) to (WEn), and may be —Y-T.

A phosphorescent emitter unit in the present application is taken to mean a unit which exhibits luminescence from an excited state having relatively high spin multiplicity, i.e. a spin state>1, such as, for example, from an excited triplet state (triplet emitter), from an MLCT mixed state or a quintet state (quintet emitter). Suitable phosphorescent emitter units are, in particular, compounds which emit light, preferably in the visible region, on suitable excitation and in addition contain at least one atom of atomic numbers>38 and <84, particularly preferably >56 and <80. Preferred phosphorescence emitters are compounds which contain copper, molybdenum, tungsten, rhenium, ruthenium, osmium, rhodium, iridium, palladium, platinum, silver, gold or europium, in particular compounds which contain iridium, platinum or copper. Examples of the emitters described above are revealed by WO 00/7065, WO 01/41512, WO 02/02714, WO 02/15645, EP 1191613, EP 1191612, EP 1191614 and WO 05/033244. In general, all phosphorescent complexes as used in accordance with the prior art for phosphorescent OLEDs and as are known to the person skilled in the art in the area of organic electroluminescence are suitable.

In a preferred embodiment, the phosphorescent emitter unit unit T contains a metal-ligand coordination compound. A metal-ligand coordination compound in the present application is taken to mean a compound having a metal atom or ion in the centre of the compound surrounded by at least one compound as ligand.

The metal-ligand coordination compound is preferably an organometallic coordination compound. An organometallic coordination compound is characterised in that a carbon atom of the ligand is bonded to the central metal via a coordination bond. However, the metal-ligand coordination compound does not necessarily have to be an organometallic coordination compound, but may also be a coordination compound which contains one of the ligands indicated below.

It is furthermore preferred for the ligand to be a chelate ligand. A chelate ligand is taken to mean a bi- or polydentate ligand, which is correspondingly able to bond to the central metal via two or more atoms.

In a further embodiment of the present invention, the metal-ligand coordination compound is preferably bonded to the group Y via a carbon atom of a ligand.

The ligands of the metal-ligand coordination compounds are preferably neutral, monoanionic, dianionic or trianionic ligands, particularly preferably neutral or monoanionic ligands. They can be monodentate, bidentate, tridentate, tetradentate, pentadentate or hexadentate, and are preferably bidentate, i.e. preferably have two coordination sites.

It is furthermore preferred in accordance with the invention for in each case at least one ligand of the metal-ligand coordination compound to be a bidentate ligand.

If the metal of the metal-ligand coordination compound is a hexacoordinated metal M, the denticity of the ligands is as follows, depending on n, which indicates the number of ligands:
n=2: M is coordinated to two tridentate ligands or to one tetradentate and one bidentate ligand or to one pentadentate and one monodentate ligand;
n=3: M is coordinated to three bidentate ligands or to one tridentate, one bidentate and one monodentate ligand or to one tetradentate and two monodentate ligands;
n=4: M is coordinated to two bidentate and two monodentate ligands or one tridentate and three monodentate ligands;
n=5: M is coordinated to one bidentate and four monodentate ligands;
n=6: M is coordinated to 6 monodentate ligands.

It is particularly preferred for M to be a hexacoordinated metal, n=3 and all ligands to be bidentate ligands.

If M is a tetracoordinated metal, the denticity of the ligands is as follows, depending on n, which indicates the number of ligands:
n=2: M is coordinated to two bidentate ligands or to one tridentate and one monodentate ligand;
n=3: M is coordinated to one bidentate and two monodentate ligands;
n=4: M is coordinated to four monodentate ligands.

Preferred neutral, monodentate ligands are selected from carbon monoxide, nitrogen monoxide, alkylcyanides, such as, for example, acetonitrile, arylcyanides, such as, for example, benzonitrile, alkylisocyanides, such as, for example, methylisonitrile, arylisocyanides, such as, for example, benzo-isonitrile, amines, such as, for example, trimethylamine, triethylamine, morpholine, phosphines, in particular halophosphines, trialkylphosphines, triarylphosphines or alkylarylphosphines, such as, for example, trifluorophosphine, trimethylphosphine, tricyclohexylphosphine, tri-tert-butylphosphine, triphenylphosphine, tris(pentafluorophenyl)phosphine, phosphites, such as, for example, trimethyl phosphite, triethyl phosphite, arsines, such as, for example, trifluoroarsine, trimethylarsine, tricyclohexylarsine, tri-tert-butylarsine, triphenylarsine, tris(pentafluorophenyl)arsine, stibines, such as, for example, trifluorostibine, trimethylstibine, tricyclohexylstibine, tri-tert-butylstibine, triphenylstibine, tris(pentafluorophenyl)stibine, nitrogen-containing heterocycles, such as, for example, pyridine, pyridazine, pyrazine, pyrimidine, triazine, and carbenes, in particular arduengo carbenes.

Preferred monoanionic, monodentate ligands are selected from hydride, deuteride, the halides F⁻, Cr⁻, Br⁻ and I⁻, alkylacetylides, such as, for example, methyl-C≡C⁻, tert-butyl-C≡C⁻, arylacetylides, such as, for example, phenyl-C≡C⁻, cyanide, cyanate, isocyanate, thiocyanate, isothiocyanate, aliphatic or aromatic alcoholates, such as, for example, methanolate, ethanolate, propanolate, isopropanolate, tert-butylate, phenolate, aliphatic or aromatic thioalcoholates, such as, for example, methanethiolate, ethanethiolate, propanethiolate, isopropanethiolate, tert-thio-butylate, thiophenolate, amides, such as, for example, dimethylamide, diethylamide, diisopropylamide, morpholide, carboxylates, such as, for example, acetate, trifluoroacetate, propionate, benzoate, aryl groups, such as, for example, phenyl, naphthyl, and anionic, nitrogen-containing heterocycles, such as pyrrolide, imidazolide, pyrazolide. The alkyl groups in these groups here are preferably C₁-C₂₀-alkyl groups, particularly preferably C₁-C₁₀-alkyl groups, very particularly preferably C₁-C₄-alkyl groups. An aryl group is also taken to mean heteroaryl groups. These groups mentioned are likewise defined like above the aliphatic and aromatic hydrocarbon radicals.

Preferred di- or trianionic ligands are O²⁻, S²⁻, carbides, which result in coordination in the form R—C≡M, nitrenes, which result in coordination in the form R—N≡M, where R generally stands for a substituent, and N³⁻.

Preferred neutral or mono- or dianionic bidentate or polydentate ligands are selected from diamines, such as, for example, ethylenediamine, N,N,N′,N′-tetramethylethylenediamine, propylenediamine, N,N,N′,N′-tetra-methylpropylenediamine, cis- or trans-diaminocyclohexane, cis- or trans-N,N,N′,N′-tetramethyldiaminocyclohexane, imines, such as, for example, 2[1-(phenylimino)ethyl]pyridine, 2[1-(2-methylphenylimino)ethyl]pyridine, 2[1-(2,6-di-iso-propylphenylimino)ethyl]pyridine, 2[1-(methylimino)ethyl]-pyridine, 2[1-(ethylimino)ethyl]pyridine, 2[1-(iso-propylimino)ethyl]pyridine, 2[1-(tert-butylimino)ethyl]pyridine, diimines, such as, for example, 1,2-bis-(methylimino)ethane, 1,2-bis(ethylimino)ethane, 1,2-bis(iso-propylimino)-ethane, 1,2-bis(tert-butylimino)ethane, 2,3-bis(methylimino)butane, 2,3-bis-(ethylimino)butane, 2,3-bis(iso-propylimino)butane, 2,3-bis(tert-butylimino)-butane, 1,2-bis(phenylimino)ethane, 1,2-bis(2-methylphenylimino)ethane, 1,2-bis(2,6-di-iso-propylphenylimino)ethane, 1,2-bis(2,6-di-tert-butylphenyl-imino)ethane, 2,3-bis(phenylimino)butane, 2,3-bis(2-methylphenylimino)-butane, 2,3-bis(2,6-di-iso-propylphenylimino)butane, 2,3-bis(2,6-di-tert-butylphenylimino)butane, heterocycles containing two nitrogen atoms, such as, for example, 2,2′-bipyridine, o-phenanthroline, diphosphines, such as, for example, bis(diphenylphosphino)methane, bis(diphenylphosphino)-ethane, bis(diphenylphosphino)propane, bis(diphenylphosphino)butane, bis(dimethylphosphino)methane, bis(dimethylphosphino)ethane, bis-(dimethylphosphino)propane, bis(diethylphosphino)methane, bis(diethyl-phosphino)ethane, bis(diethylphosphino)propane, bis(di-tert-butylphos-phino)methane, bis(di-tert-butylphosphino)ethane, bis(tert-butylphosphino)-propane, 1,3-diketonates derived from 1,3-diketones, such as, for example, acetylacetone, benzoylacetone, 1,5-diphenylacetylacetone, dibenzoyl-methane, bis(1,1,1-trifluoroacetyl)methane, 3-ketonates derived from 3-ketoesters, such as, for example, ethyl acetoacetate, carboxylates derived from aminocarboxylic acids, such as, for example, pyridine-2-carboxylic acid, quinoline-2-carboxylic acid, glycine, N,N-dimethylglycine, alanine, N,N-dimethylaminoalanine, salicyliminates derived from salicyl-imines, such as, for example, methylsalicylimine, ethylsalicylimine, phenyl-salicylimine, dialcoholates derived from dialcohols, such as, for example, ethylene glycol, 1,3-propylene glycol, and dithiolates derived from dithiols, such as, for example, 1,2-ethylenedithiol, 1,3-propylenedithiol.

Preferred tridentate ligands are borates of nitrogen-containing heterocycles, such as, for example, tetrakis(1-imidazolyl) borate and tetrakis-(1-pyrazolyl) borate.

Preference is furthermore given to bidentate monoanionic ligands which, with the metal, have a cyclometallated five-membered ring or six-membered ring having at least one metal-carbon bond, in particular a cyclometallated five-membered ring. These are, in particular, ligands as generally used in the area of phosphorescent metal complexes for organic electroluminescent devices, i.e. ligands of the phenylpyridine, naphthyl-pyridine, phenylquinoline, phenylisoquinoline, etc., type, each of which may be substituted by one or more radicals R. A multiplicity of ligands of this type is known to the person skilled in the art in the area of phosphorescent electroluminescent devices, and he will be able to select further ligands of this type as ligands for the structural units of the formula (I). In general, the combination of two groups, as represented by the following formulae (L-1) to (L-28), is particularly suitable for this purpose, where one group is bonded via a neutral nitrogen atom or a carbene atom and the other group is bonded via a negatively charged carbon atom or a nega-tively charged nitrogen atom. The ligand can then be formed from the groups of the formulae (L-1) to (L-28) through these groups bonding to one another, in each case at the position denoted by #. The position at which the groups coordinate to the metal are denoted by *.

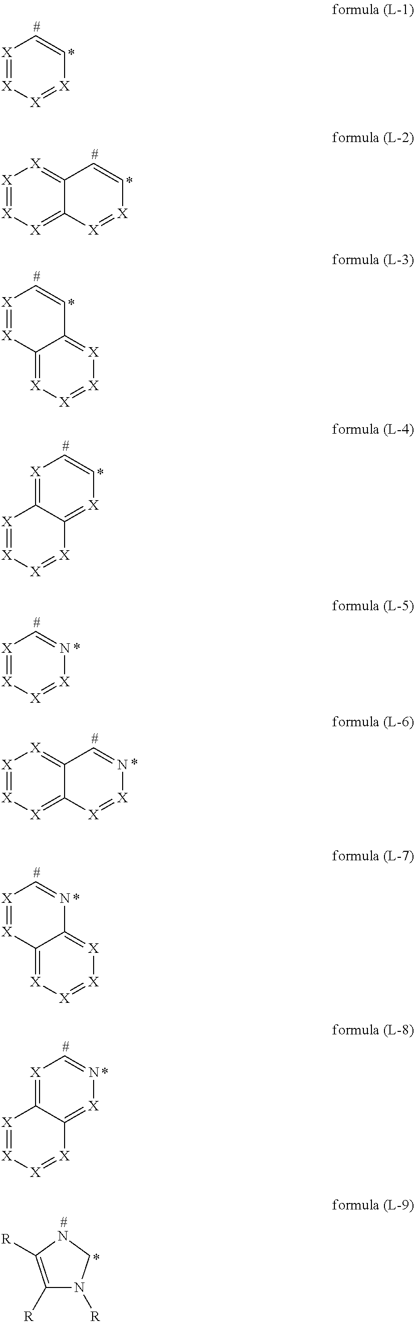

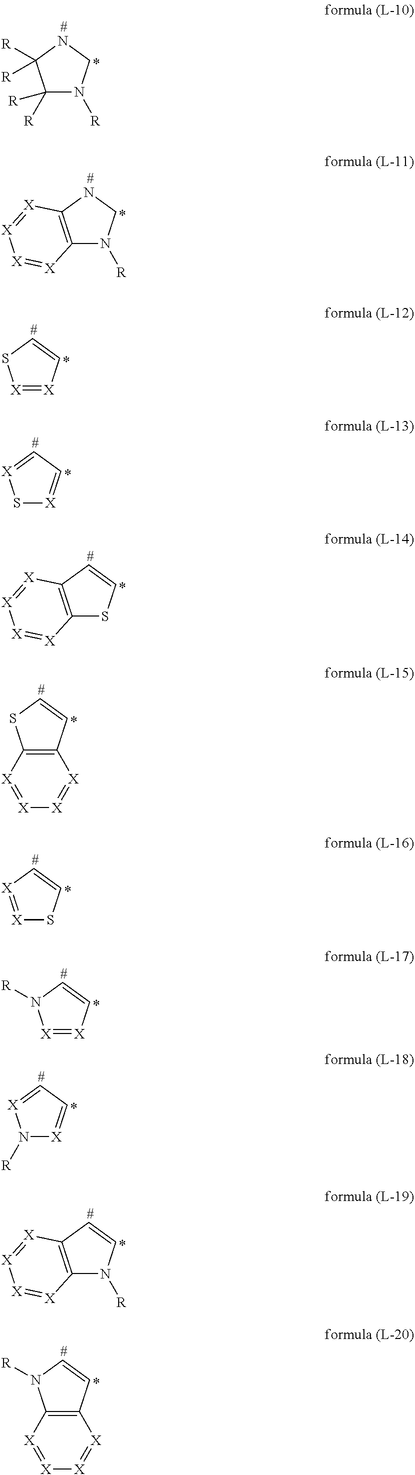

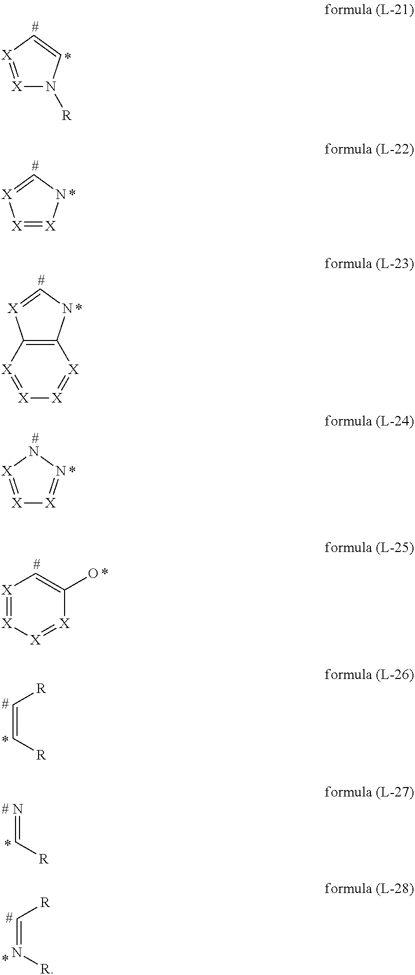

The symbol R here stands on each occurrence, identically or differently, for one of the following radicals: alkyl, cycloalkyl, alkylsilyl, silyl, arylsilyl, alkoxyalkyl, arylalkoxyalkyl, alkylthioalkyl, alkyl sulfone, alkyl sulfoxide, where the alkyl groups preferably each, independently of one another, have 1 to 12 C atoms, where one or more H atoms may be replaced by F, Cl, Br, I, alkyl or cycloalkyl and where one or more non-adjacent CH₂ groups may be replaced by a heteroatom, such as NH, O or S, or an aromatic or heteroaromatic hydrocarbon radical having 5 to 40 aromatic ring atoms. X stands for N or CH. Particularly preferably a maximum of three symbols X in each group stand for N, particularly preferably a maximum of two symbols X in each group stand for N, very particularly preferably a maximum of one symbol X in each group stands for N. Especially preferably all symbols X stand for CH.

The term “alkyl” is taken to mean an aliphatic hydrocarbon radical as defined above.

The term “aryl” or “aryl group” is taken to mean an aromatic or heteroaromatic hydrocarbon radical, as defined above.

“Cycloalkyl” in the present invention is taken to mean a cyclic alkyl group as defined above, preferably having 3 to 8, particularly preferably 5 to 8 and very particularly preferably 5 or 6 carbon atoms.

The term “alkylsilyl” is taken to mean mono(C₁₋₁₂-alkyl)silylgroups, di(C₁₋₁₂-alkyl)silylgroups and tri-(C₁₋₁₂-alkyl)silyl groups.

A “mono(C₁₋₁₂-alkyl)silyl group” in the present invention is taken to mean an (SiH₂) group which is linked to a linear or branched alkyl group (as defined above) having 1 or 3 to 12 carbon atoms respectively, particularly preferably 1 or 3 to 6 carbon atoms respectively. A “di(C₁₋₁₂-alkyl)silyl group” in the present invention is taken to mean an (SiH) unit which is linked to two linear or branched alkyl groups (as defined above), on each occurrence identical or different, having 1 or 3 to 12 carbon atoms respectively, particularly preferably 1 or 3 to 6 carbon atoms respectively. A “tri(C₁₋₁₂-alkyl)silylgroup” in the present invention is taken to mean an (Si) unit which is linked to three linear or branched alkyl groups (as defined above), on each occurrence identical or different, having 1 or 3 to 12 carbon atoms respectively, particularly preferably 1 or 3 to 6 carbon atoms respectively. The examples indicated above in connection with the definition of aliphatic hydrocarbon radicals also apply to the alkyl groups present here, if they have the corresponding number of carbon atoms.

“Silyl” in the present invention is taken to mean a silyl group having 1 or 3 to 5 silicon atoms, which is linear or branched. Examples thereof are monosilyl, disilyl, trisilyl, tetrasilyl and pentasilyl.

“Arylsilyl” in the present invention is taken to mean an Si₁-silylgroup which is substituted by one, two or three, mono- or polycyclic, aromatic or heteroaromatic ring systems having 5 to 60 aromatic ring atoms.

“Alkoxyalkyl” in the present invention is taken to mean a monovalent ether unit having two linear or branched alkyl groups having 1 or 3 to 12, particularly preferably 1 or 3 to 6 carbon atoms respectively, which are bonded via an oxygen atom. The examples indicated above in connection with the definition of aliphatic hydrocarbon radicals also apply to the alkyl groups present here, if they have the corresponding number of carbon atoms.

“Arylalkoxyalkyl” in the present invention is taken to mean a monovalent unit as defined above for “alkoxyalkyl”, where one alkyl group is substituted by an aryl which represents a mono- or polycyclic, aromatic or heteroaromatic ring system having 5 to 60 aromatic ring atoms as defined above. The examples indicated above in connection with the definition of aliphatic hydrocarbon radicals also apply to the alkyl groups present here, if they have the corresponding number of carbon atoms.

“Alkylthioalkyl” in the present invention is taken to mean a monovalent thioether unit having two linear or branched alkyl groups having 1 or 3 to 12, particularly 1 or 3 to 6 carbon atoms respectively, which are bonded via a sulfur atom. The examples indicated above in connection with the definition of aliphatic hydrocarbon radicals also apply to the alkyl groups present here, if they have the corresponding number of carbon atoms.

“Alkyl sulfone” in the present invention is taken to mean an S(═O)₂— unit which is substituted by an alkyl group having 1 to 12 carbon atoms. The examples indicated above in connection with the definition of aliphatic hydrocarbon radicals also apply to the alkyl groups present here, if they have the corresponding number of carbon atoms.

“Alkyl sulfoxide” in the present invention is taken to mean an —S(═O)— unit which is substituted by an alkyl group having 1 to 12 carbon atoms. The examples indicated above in connection with the definition of aliphatic hydrocarbon radicals also apply to the alkyl groups present here, if they have the corresponding number of carbon atoms.

Likewise preferred ligands of the metal-ligand coordination compound are η⁵-cyclopentadienyl, η⁵-pentamethylcyclopentadienyl, η⁶-benzene or η⁷-cycloheptatrienyl, each of which may be substituted by one or more radicats R.

Likewise preferred ligands are 1,3,5-cis-cyclohexane derivatives, in particular of the formula (L-29), 1,1,1-tri(methylene)methane derivatives, in particular of the formula (L-30), and 1,1,1-trisubstituted methanes, in particular of the formulae (L-31) and (L-32),

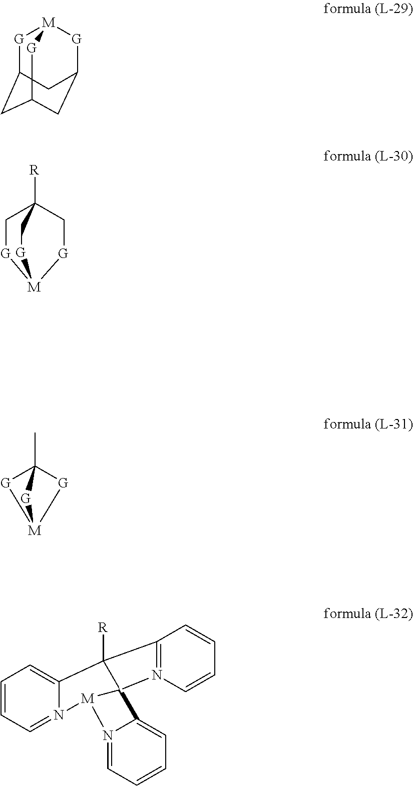

where the coordination to the metal M is depicted in each of the formulae, R has the meaning given above, and G stands, identically or differently on each occurrence, for O⁻, S⁻, COO⁻, P(R)₂ or N(R)₂.

The phosphorescent emitter unit is preferably bonded to Y via one of the ligands mentioned above. One of the H atoms is preferably not present here and a link to Y is formed in place of the ligand.

The ligand is preferably an organic ligand which contains a unit (called ligand unit below) which is represented by the following formula (IV):

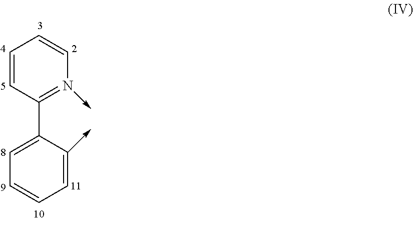

where the atoms from which the arrows point away are coordinated to the metal atom, and the numbers 2 to 5 and 8 to 11 merely represents a numbering in order to distinguish the C atoms. The organic ligand unit of the formula (IV) may, instead of hydrogen at positions 2, 3, 4, 5, 8, 9, 10 and 11, independently of one another, have a substituent which is selected from the group consisting of C₁₋₆-alkyl, C₅₋₂₀-aryl, 5- to 14-membered heteroaryl and further substituents.

The expression “C₁₋₅-alkyl” used herein denotes a linear or branched alkyl group having 1 to 6 carbon atoms. Examples of such carbon atoms are methyl, ethyl, n-propyl, isopropyl, n-butyl, isobutyl, sec-butyl (1-methyl-propyl), tert-butyl, isopentyl, n-pentyl, tert-pentyl (1,1-dimethylpropyl), 1,2-dimethylpropyl, 2,2-dimethylpropyl (neopentyl), 1-ethylpropyl, 2-methylbutyl, n-hexyl, isohexyl, 1,2-dimethylbutyl, 1-ethyl-1-methylpropyl, 1-ethyl-2-methylpropyl, 1,1,2-trimethylpropyl, 1,2,2-trimethylpropyl, 1-ethylbutyl, 1-methylbutyl, 1,1-dimethylbutyl, 2,2-dimethylbutyl, 1,3-dimethylbutyl, 2,3-dimethylbutyl, 3,3-dimethylbutyl, 2-ethylbutyl, 1-methylpentyl, 2-methyl-pentyl and 3-methylpentyl, where methyl and ethyl are preferred.

The expression “C₆₋₂₀-aryl” denotes an aromatic ring system having 6 to 20 carbon atoms. An aromatic or heteroaromatic ring system in the sense of the present invention is intended to be taken to mean a system which does not necessarily contain only aromatic or heteroaromatic groups, but instead in which, in addition, a plurality of aromatic or heteroaromatic groups may be interrupted by a short non-aromatic unit (<10% of the atoms other than H, preferably <5% of the atoms other than H), such as, for example, sp³-hybridised C, O or N.

Aromatic groups can be monocyclic or polycyclic, i.e. they can have one ring (for example phenyl) or two or more rings, which may also be condensed (for example naphthyl) or covalently linked (for example biphenyl), or contain a combination of condensed and linked rings. Preference is given to fully conjugated aromatic groups.

Preferred aromatic ring systems are, for example, phenyl, biphenyl, triphenyl, naphthyl, anthracene, binaphthyl, phenanthrene, dihydrophenanthrene, pyrene, dihydropyrene, chrysene, perylene, tetracene, benzopyrene, fluorene, indene, indenofluorene and spirobifluorene.

“5- to 14-membered heteroaryl” is taken to mean an aromatic group in which one or more carbon atom(s) has (have) been replaced by an N, O or S. Examples thereof include the following: 5-membered rings, such as pyrrole, pyrazole, imidazole, 1,2,3-triazole, 1,2,4-triazole, tetrazole, furan, thiophene, selenophene, oxazole, isoxazole, 1,2-thiazole, 1,3-thiazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 6-membered rings, such as pyridine, pyridazine, pyrimidine, pyrazine, 1,3,5-triazine, 1,2,4-triazine, 1,2,3-triazine, 1,2,4,5-tetrazine, 1,2,3,4-tetrazine, 1,2,3,5-tetrazine, or condensed groups, such as indole, isoindole, indolizine, indazole, benzimidazole, benzotriazole, purine, naphthimidazole, phenanthrimidazole, pyridimidazole, pyrazinimidazole, quinoxalin-imidazole, benzoxazole, naphthoxazole, anthroxazole, phenanthroxazole, isoxazole, benzothiazole, benzofuran, isobenzofuran, dibenzofuran, quinoline, isoquinoline, pteridine, benzo-5,6-quinoline, benzo-6,7-quinoline, benzo-7,8-quinoline, benzoisoquinoline, acridine, phenothiazine, phenoxazine, benzopyridazine, benzopyrimidine, quinoxaline, phenazine, naphthyridine, azacarbazole, benzocarboline, phenanthridine, phenanthroline, thieno[2,3b]thiophene, thieno[3,2b]thiophene, dithienothiophene, isobenzothiophene, dibenzothiophene, benzothiadiazothiophene, or combinations of these groups. The heteroaryl groups may also be substituted by alkyl, alkoxy, thioalkyl, fluorine, fluoroalkyl or further aryl or heteroaryl groups.

Further possible substituents on the ligand unit of the formula (IV) are preferably selected from the group consisting of silyl, sulfo, sulfonyl, formyl, amine, imine, nitrile, mercapto, nitro, halogen, hydroxyl or combinations of these groups. Preferred substituents are, for example, solubility-promoting groups, such as alkyl or alkoxy, electron-withdrawing groups, such as fluorine, nitro or nitrile, or substituents for increasing the glass transition temperature (Tg) in the polymer. Particularly preferred substituents are, for example, F, Cl, Br, I, —CN, —NO₂, —NCO, —NCS, —OCN, —SCN, —C(═O)N(R)₂, —C(═O)R, —C(═O)R and —N(R)₂, in which R is a hydrogen, alkyl or aryl, optionally substituted silyl, aryl having 4 to 40, preferably 6 to 20 C atoms, and straight-chain or branched alkyl, alkoxy, alkylcarbonyl, alkoxycarbonyl, alkylcarbonyloxy or alkoxycarbonyloxy having 1 to 22 C atoms, in which one or more H atoms may optionally be replaced by F or Cl.

It is furthermore preferred for two adjacent carbon atoms on the phenyl ring or pyridyl ring of the ligand unit of the formula (IV) to be bridged via a —CH═CH—CH═CH— group, where, in the case of the phenyl ring, a naphthyl unit and, in the case of the pyridyl ring, an azanaphthyl unit forms. These may in turn carry via a further group —CH═CH—CH═CH— group bridging via two adjacent carbon atoms. In a further preferred embodiment, the carbon atoms at positions 5 and 8 are bridged via a —CH═CH— group. Further bridges between phenyl units of the ligand unit can be divalent (CH₃)C units, which are preferably linked in such a way that a further 6-membered ring forms.

Preferred examples of the ligands of the formula (IV) are the following compounds (IV-1) to (IV-10):

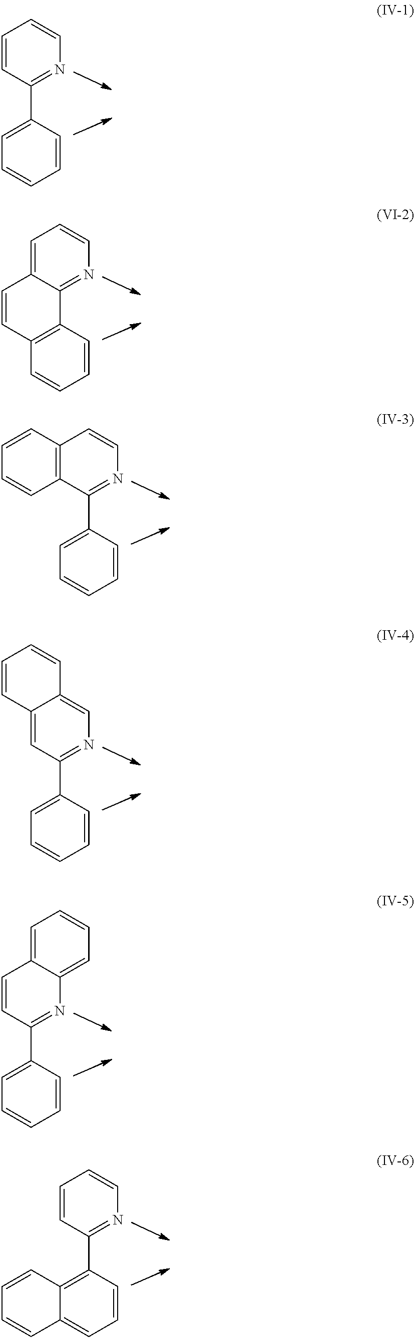 [SMILES: c1ccc(-c2ccccn2)cc1 ; c1ccc2c(c1)ccc1cccnc12 ; c1ccc(-c2nccc3ccccc23)cc1 ; c1ccc(-c2cc3ccccc3cn2)cc1 ; c1ccc(-c2ccc3ccccc3n2)cc1 ; c1ccc(-c2cccc3ccccc23)nc1]

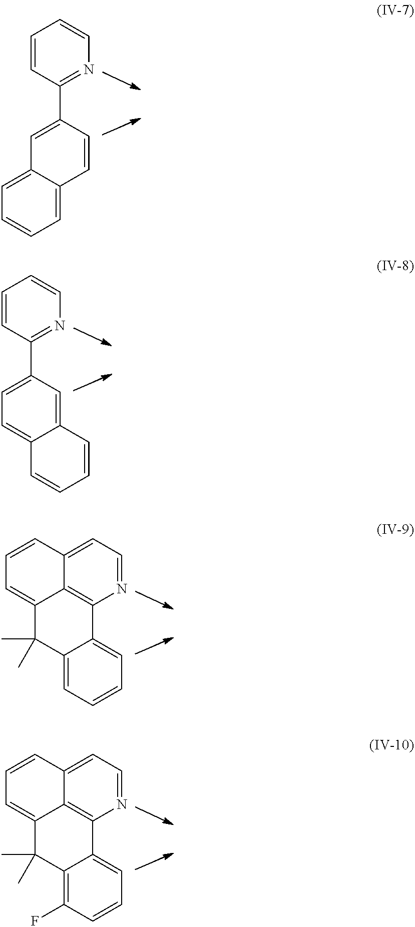

For the purposes of the present invention, particular preference is given to the compounds (IV-1), (IV-3) and (IV-10).

Furthermore, the ligand is preferably bonded to the group Y via a C atom in the 2-, 3-, 4-, 5-, 8-, 9-, 10- or 11-position. The ligand is particularly preferably bonded to the group Y via position 9 or 11, very particularly preferably via position 9.

In a further embodiment of the present invention, two ligand units which are represented by the formula (IV) are preferably each bonded independently via a C atom in the 2- or 11-position, particularly preferably in the 11-position, preferably to an sp³-hybridised atom of the group Y, where a tetradentate chelate ligand is formed.

Besides the above-mentioned ligand units which are bonded to Y, the coordination compound may contain further ligands, which are preferably not bonded to Y. This further ligand is likewise defined like the ligands mentioned above, with the difference that none of the H atoms has been replaced by a bond to Y. In other words, this ligand preferably contains a hydrogen radical instead of the bond to Y at the corresponding site. Preferred examples of the further ligand are the same as mentioned above. Particularly preferred examples are ligands of the above-mentioned formulae (IV-1) to (IV-10). The further ligand is particularly preferably a ligand of the formulae (IV-1), (IV-3) and (IV-10).

The metal of the metal-ligand coordination compound is preferably a transition metal, a main-group metal, a lanthanoid or an actinoid. If the metal is a main-group metal, it is preferably a metal from the third, fourth or fifth main group, in particular tin. If the metal is a transition metal, it is preferably Ir, Ru, Os, Pt, Zn, Mo, W, Rh or Pd, in particular Ir and Pt. Eu is preferred as lanthanoid.

Preference is given to metal-ligand coordination compounds in which the metal is a transition metal, in particular a tetracoordinated, a pentacoordinated or a hexacoordinated transition metal, particularly preferably selected from the group consisting of chromium, molybdenum, tungsten, rhenium, ruthenium, osmium, rhodium, iridium, nickel, palladium, platinum, copper, silver and gold, very particularly preferably molybdenum, tungsten, rhenium, ruthenium, osmium, iridium, platinum, copper and gold. Particular preference is given to iridium and platinum. The metals here can be in various oxidation states. The above-mentioned metals here are preferably in the oxidation states Cr(0), Cr(II), Cr(III), Cr(IV), Cr(VI), Mo(0), Mo(II), Mo(III), Mo(IV), Mo(VI), W(O), W(II), W(III), W(IV), W(VI), Re(I), Re(II), Re(III), Re(IV), Ru(II), Ru(III), Os(II), Os(III), Os(IV), Rh(I), Rh(III), Ir(I), Ir(III), Ir(IV), Ni(0), Ni(II), Ni(IV), Pd(II), Pt(II), Pt(IV), Cu(I), Cu(II), Cu(III), Ag(I), Ag(II), Au(I), Au(III) and Au(V); particular preference is given to Mo(0), W(0), Re(I), Ru(II), Os(II), Rh(III), Ir(III), Pt(II) and Cu(I), very particularly preferably Ir(III) and Pt(II).

In a preferred embodiment of the present invention, the metal is a tetracoordinated metal having one, two, three or four ligands. In this way, the ligands can be mono-, bi-, tri- or tetradentate ligands. If the metal is coordinated to one ligand, it is a tetradentate ligand. If the metal is coordinated to two ligands, either both ligands are bidentate ligands, or one is a tridentate ligand and one is a monodentate ligand. If the metal is coordinated to three ligands, one ligand is a bidentate ligand and two are monodentate ligands. If the metal is coordinated to four ligands, all ligands are monodentate.

In a further preferred embodiment of the invention, the metal is a hexacoordinated metal having one, two, three, four, five or six ligands. In this way, the ligands can be mono-, bi-, tri-, tetra-, penta- or hexadentate ligands. If the metal is coordinated to one ligand, it is a hexadentate ligand. If the metal is coordinated to two ligands, either both are tridentate ligands or one is a bidentate ligand and one is a tetradentate ligand or one is a monodentate ligand and one is a pentadentate ligand. If the metal is coordinated to three ligands, either all three ligands are bidentate ligands or one is a tridentate ligand, one is a bidentate ligand and one is a monodentate ligand, or one is a tetradentate ligand and two are monodentate ligands. If the metal is coordinated to four ligands, one ligand is a tridentate ligand and three are monodentate ligands or two are bidentate ligands and two are monodentate ligands. If the metal is coordinated to five ligands, one is a bidentate ligand and four are monodentate ligands. If the metal is coordinated to six ligands, all ligands are monodentate.

The metal centre of the organic coordination compound is preferably a metal atom in the oxidation state 0. And the metal-ligand coordination compound is preferably a charge-neutral compound.

In a very particularly preferred embodiment, the metal centre is Pt or Ir. If the metal centre is Pt, it preferably has the coordination number 4. In the case of Ir as metal centre, the coordination number is preferably 6.

It is furthermore preferred for Pt to be coordinated by two ligand units of the formula (IV) and for Ir to be coordinated by three ligand units of the formula (IV) in the manner indicated above.

Surprisingly, it has been found that an electroluminescent polymer which contains at least one structural unit of the formula (I) has very good properties. In particular, it exhibits high efficiencies and increases the lifetime compared with previous reference systems.

In the present application, the term “polymer” is taken to mean both polymeric compounds, oligomeric compounds, and dendrimers. The polymeric compounds according to the invention preferably have 10 to 10,000, particularly preferably 20 to 5000 and in particular 50 to 2000 structural units. The oligomeric compounds according to the invention preferably have 2 to 9 structural units. The branching factor of the polymers here is between 0 (linear polymer, no branching points) and 1 (fully branched dendrimer).

The polymers according to the invention are either conjugated, partially conjugated or non-conjugated polymers. Conjugated or partially conjugated polymers are preferred.

The structural units of the formula (I) can, in accordance with the invention, be incorporated into the main chain or into the side chain of the polymer.

“Conjugated polymers” in the sense of the present application are polymers which contain principally sp²-hybridised (or optionally also sp-hybridised) carbon atoms in the main chain, which may also be replaced by corresponding heteroatoms. In the simplest case, this means the alternating presence of double and single bonds in the main chain, but also polymers containing units such as, for example, meta-linked phenylene are intended to be regarded as conjugated polymers in the sense of this application. “Principally” means that naturally (involuntarily) occurring defects which result in conjugation interruptions do not devalue the term “conjugated polymer”. Furthermore, the term conjugated is likewise used in this application if, for example, arylamine units, arylphosphine units, certain heterocycles (i.e. conjugation via N, O or S atoms) and/or organometallic complexes (i.e. conjugation via the metal atom) are located in the main chain. An analogous situation applies to conjugated dendrimers. By contrast, units such as, for example, simple alkyl bridges, (thio)ether, ester, amide or imide links are clearly defined as non-conjugated segments. A partially conjugated polymer in the sense of the present application is intended to be taken to mean a polymer which contains conjugated regions which are separated from one another by non-conjugated sections, specific conjugation interrupters (for example spacer groups) or branches, for example in which relatively long conjugated sections in the main chain are interrupted by non-conjugated sections, or which contains relatively long conjugated sections in the side chains of a polymer which is non-conjugated in the main chain. Conjugated and partially conjugated polymers may also include conjugated, partially conjugated or other dendrimers.

The term “dendrimer” in the present application is intended to be taken to mean a highly branched compound built up from a multifunctional centre (core) to which branched monomers are bonded in a regular structure, giving a tree-like structure. Both the centre and the monomers here may adopt any desired branched structures which consist both of purely organic units and also organometallic compounds or coordination compounds. “Dendrimer” here is generally intended to be understood as described, for example, by M. Fischer and F. Vögtle (Angew. Chem., Int. Ed. 1999, 38, 885).

In a further preferred embodiment of the present invention, units of the formula (I) are conjugated with the main polymer chain. This can be achieved on the one hand by these units being incorporated into the main chain of the polymer in such a way that the conjugation of the polymer, as described above, is thereby retained. On the other hand, these units can also be linked into the side chain of the polymer in such a way that conjugation with the main chain of the polymer exists. This is the case, for example, if the linking to the main chain takes place only via sp²-hybridised (or optionally also via sp-hybridised) carbon atoms, which may also be replaced by corresponding heteroatoms. However, if the linking takes place through units such as, for example, simple (thio)ether bridges, esters, amides or alkylene chains, the units of the formula (I) are defined as non-conjugated with the main chain. However, “are conjugated” here means only the backbone of the structural units of the formula (I) and not necessarily also that the phosphorescent emitter unit T is conjugated with the main polymer chain via the backbone.

In a further embodiment of the present invention, the polymer according to the invention contains not only one structural unit of the formula (I), but may also contain combinations thereof, i.e. the polymer can be obtained by copolymerisation of a plurality of structural units of the formula (I).

Besides the structural units of the formula (I), the polymer according to the invention preferably also contains further structural units which are different from those of the formula (I).

In the polymer according to the invention, the proportion of the units of the formula (I) is preferably 0.001 to 50 mol %, particularly preferably 0.01 to 40 mol %, and very particularly preferably 0.05 to 30 mol %, based on the total number of the structural units of the polymer.

Besides one or more structural units of the formula (I), the polymers according to the invention may also contain further structural units. These are, inter alia, those as disclosed and listed extensively in WO 02/077060 A1 and in WO 2005/014689 A2. These are incorporated into the present invention by way of reference. The further structural units can originate, for example, from the following classes:
Group 1: units which influence the hole-injection and/or hole-transport properties of the polymers;
Group 2: units which influence the electron-injection and/or electron-transport properties of the polymers;
Group 3: units which have combinations of individual units from group 1 and group 2;
Group 4: units which modify the emission characteristics to such an extent that electrophosphorescence can be obtained instead of electrofluorescence;
Group 5: units which improve the transfer from the so-called singlet state to the triplet state;
Group 6: units which influence the emission colour of the resultant polymers;
Group 7: units which are typically used as backbone;
Group 8: units which influence the film morphology and/or the rheology of the resultant polymers.

Preferred polymers according to the invention are those in which at least one structural unit has hole-transport properties, i.e. which contain units from group 1 and/or 2.

Structural units from group 1 which have hole-injection and/or hole-transport properties are, for example, triarylamine, benzidine, tetraaryl-paraphenylenediamine, triarylphosphine, phenothiazine, phenoxazine, dihydrophenazine, thianthrene, dibenzo-para-dioxin, phenoxathiyne, carbazole, azulene, thiophene, pyrrole and furan units and further O-, S- or N-containing heterocycles having a high HOMO (HOMO=highest occupied molecular orbital). These arylamines and heterocycles preferably result in an HOMO in the polymer of greater than −5.8 eV (against vacuum level), particularly preferably greater than −5.5 eV.

Structural units from group 2 which have electron-injection and/or electron-transport properties are, for example, pyridine, pyrimidine, pyridazine, pyrazine, oxadiazole, quinoline, quinoxaline, anthracene, benzanthracene, pyrene, perylene, benzimidazole, triazine, ketone, phosphine oxide and phenazine units, but also triarylboranes and further O-, S- or N-containing heterocycles having a low LUMO (LUMO=lowest unoccupied molecular orbital). These units in the polymer preferably result in an LUMO of less than −12.5 eV (against vacuum level), particularly preferably less than −2.0 eV.

It may be preferred for the polymers according to the invention to contain units from group 3 containing structures which increase the hole mobility and structures which influence, preferably increase, the electron mobility (i.e. units from group 1 and 2) bonded directly to one another or structures which influence, preferably increase, both the hole mobility and the electron mobility. Some of these units can serve as emitters and shift the emission colour into the green, yellow or red. Their use is thus suitable, for example, for the generation of other emission colours from originally blue-emitting polymers.

Structural units from group 4 are those which are able to emit light from the triplet state with high efficiency, even at room temperature, i.e. exhibit electrophosphorescence instead of electrofluorescence, which frequently causes an increase in the energy efficiency. Suitable for this purpose are firstly compounds which contain heavy atoms having an atomic number of greater than 36. Preference is given to compounds which contain d- or f-transition metals which satisfy the above-mentioned condition. Particular preference is given here to corresponding structural units which contain elements from group 8 to 10 (Ru, Os, Rh, Ir, Pd, Pt). Suitable structural units for the polymers according to the invention here are, for example, various complexes, as described, for example, in WO 02/068435 A1, WO 02/081488 A1, EP 1239526 A2 and WO 2004/026886 A2. Corresponding monomers are described in WO 02/068435 A1 and in WO 2005/042548 A1.

Structural units from group 5 are those which improve the transfer from the singlet state to the triplet state and which, employed in support of the structural units from group 3, improve the phosphorescence properties of these structural elements. Suitable for this purpose are, in particular, carbazole and bridged carbazole dimer units, as described, for example, in WO 2004/070772 A2 and WO 2004/113468 A1. Also suitable for this purpose are ketones, phosphine oxides, sulfoxides, sulfones, silane derivatives and similar compounds, as described, for example, in WO 2005/040302 A1.

Structural units from group 6, besides those mentioned above, are those which have at least one further aromatic structure or another conjugated structure which do not fall under the above-mentioned groups, i.e. which have only little influence on the charge-carrier mobilities, which are not organometallic complexes or which do not influence the singlet-triplet transfer. Structural elements of this type can influence the emission colour of the resultant polymers. Depending on the unit, they can therefore also be employed as emitters. Preference is given here to aromatic structures having 6 to 40 C atoms or also tolan, stilbene or bisstyrylarylene units, each of which may be substituted by one or more radicals R. Particular preference is given here to the incorporation of 1,4 phenylene, 1,4-naphthylene, 1,4- or 9,10-anthrylene, 1,6-, 2,7- or 4,9-pyrenylene, 3,9- or 3,10-perylenylene, 4,4′-biphenylylene, 4,4″ terphenylylene, 4,4′-bi-1,1′-naphthylylene, 4,4′-tolanylene, 4,4′-stilbenzylene, 4,4″ bisstyrylarylene, benzothiadiazole and corresponding oxygen derivatives, quinoxaline, phenothiazine, phenoxazine, dihydrophenazine, bis(thiophenyl)arylene, oligo(thiophenylene), phenazine, rubrene, pentacene or perylene derivatives, which are preferably substituted, or preferably conjugated push-pull systems (systems which are substituted by donor and acceptor substituents) or systems such as squarines or quinacridones, which are preferably substituted.

Structural units from group 7 are units which contain aromatic structures having 6 to 40 C atoms, which are typically used as polymer backbone. These are, for example, 4,5-dihydropyrene derivatives, 4,5,9,10-tetrahydropyrene derivatives, fluorene derivatives, 9,9′ spirobifluorene derivatives, phenanthrene derivatives, 9,10-dihydrophenanthrene derivatives, 5,7-dihydrodibenzoxepine derivatives and cis- and trans-indenofluorene derivatives.

Structural units from group 8 are those which influence the film morphology and/or the rheology of the polymers, such as, for example, siloxanes, long alkyl chains or fluorinated groups, but also particularly rigid or flexible units, such as, for example, liquid crystal-forming units or crosslinkable groups.

Preference is given to polymers according to the invention which, besides the structural units of the formula (I), simultaneously additionally contain one or more units selected from groups 1 to 8 which are different from the structural units according to the invention. It may likewise be preferred for more than one structural unit from one group to be present simultaneously.

Preference is given here to polymers according to the invention which, besides at least one structural unit of the formula (I), also contain units from group 7, particularly preferably at least 50 mol % of these units, based on the total number of structural units in the polymer.

It is likewise preferred for the polymers according to the invention to contain units which improve charge transport or charge injection, i.e. units from group 1 and/or 2; a proportion of 0.5 to 30 mol % of these units is particularly preferred; a proportion of 1 to 10 mol % of these units is very partitularly preferred.

It is furthermore particularly preferred for the polymers according to the invention to contain structural units from group 7 and units from group 1 and/or 2, in particular at least 50 mol % of units from group 7 and 0.5 to 30 mol % of units from group 1 and/or 2.

The polymers according to the invention are either homopolymers containing structural units of the formula (I) or copolymers. The polymers according to the invention can be linear, branched or crosslinked. Besides one or more structural units of the formula (I), or preferred sub-formlae thereof, copolymers according to the invention may potentially have one or more further structural units from groups 1 to 8 mentioned above.

The copolymers according to the invention may have random, alternating or block-like structures or have a plurality of these structures in an alternating arrangement. The way in which copolymers having block-like structures can be obtained and which further structural elements are particularly preferred for this purpose is described in detail, for example, in WO 2005/014688 A2. The latter is incorporated into the present application by way of reference. It should likewise again be emphasised at this point that the polymer may also have dendritic structures.

The polymers according to the invention containing structural units of the formula (I) are accessible readily and in high yields.

The polymers according to the invention have advantageous properties, in particular long lifetimes, high efficiencies and good colour coordinates.

The polymers according to the invention are generally prepared by polymerisation of one or more types of monomer, of which at least one monomer results in structural units of the formula (I) in the polymer. Suitable polymerisation reactions are known to the person skilled in the art and are described in the literature. Particularly suitable and preferred polymerisation reactions which result in C—C or C—N links are the following:

(A) SUZUKI polymerisation;
(B) YAMAMOTO polymerisation;
(C) STILLE polymerisation;
(D) HARTWIG-BUCHWALD polymerisation;
(E) NEGISHI polymerisation;
(F) SONOGASHIRA polymerisation;
(G) HIYAMA polymerisation; and
(H) HARTWIG-BUCHWALD polymerisation.

The way in which the polymerisation can be carried out by these methods and the way in which the polymers can then be separated off from the reaction medium and purified is known to the person skilled in the art and is described in detail in the literature, for example in WO 03/048225 A2, WO 2004/037887 A2 and WO 2004/037887 A2.

The C—C linking reactions are preferably selected from the groups of the SUZUKI coupling, the YAMAMOTO coupling and the STILLE coupling; the C—N linking reaction is preferably a HARTWIG-BUCHWALD coupling.

The present invention thus also relates to a process for the preparation of the polymers according to the invention, which is characterised in that they are prepared by SUZUKI polymerisation, YAMAMOTO polymerisation, STILLE polymerisation or HARTWIG-BUCHWALD polymerisation.

The dendrimers according to the invention can be prepared by processes known to the person skilled in the art or analogously thereto. Suitable processes are described in the literature, such as, for example, in Frechet, Jean M. J.; Hawker, Craig J., “Hyperbranched polyphenylene and hyperbranched polyesters: new soluble, three-dimensional, reactive polymers”, Reactive & Functional Polymers (1995), 26(1-3), 127-36; Janssen, H. M.; Meijer, E. W., “The synthesis and characterization of dendritic molecules”, Materials Science and Technology (1999), 20 (Synthesis of Polymers), 403-458; Tomalia, Donald A., “Dendrimer molecules”, Scientific American (1995), 272(5), 62-6, WO 02/067343 A1 and WO 2005/026144 A1.

The synthesis of the units from group 1 to 8 described above and the further emitting units is known to the person skilled in the art and is described in the literature, for example in WO 2005/014689 A2, WO 2005/030827 A1 and WO 2005/030828 A1. These documents and the literature cited therein are incorporated into the present application by way of reference.

For the synthesis of the polymers according to the invention, the corresponding monomers are required. Monomers which result in structural units of the formula (I) in the polymers according to the invention are compounds which are correspondingly substituted and have in two positions suitable functionalities which allow this monomer unit to be incorporated into the polymer. These monomers are novel and are likewise a subject-matter of the present invention.

Accordingly, the present invention also relates to compounds of the following formula (II), which can be incorporated as structural units into the polymers according to the invention,

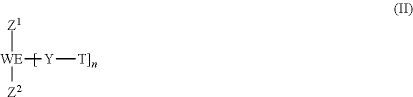

where the symbols and indices used have the following meanings:
Z¹ and Z² are selected, independently of one another, from R¹, halogen, O-tosylate, O-triflate, O—SO₂R³, B(OR³)₂ and Sn(R³)₃;
WE, Y, T and n have the same meanings as defined above for the structural units of the formula (I); and
R⁴³ is selected on each occurrence, independently of one another, from the group consisting of hydrogen, an aliphatic hydrocarbon radical having 1 to 20 C atoms and an aromatic hydrocarbon radical having 1 to 20 C atoms, or where two or more radicals R³ may form a ring system with one another.

Preferably, at least one of the radicals Z¹, Z² is selected from halogen, O-tosylate, O-triflate, O—SO₂R³, B(OR³)₂ and Sn(R³)₃. Particularly preferably, both radicals Z¹, Z² are selected from halogen, O-tosylate, O-triflate, O—SO₂R³, B(OR³)₂ and Sn(R³)₃.

The embodiments of the structural units of the formula (I) which are preferred in the present invention also represent embodiments of the compounds of the formula (II) which are preferred in accordance with the invention.

In the present invention, halogen is taken to mean fluorine, chlorine, bromine or iodine, where chlorine, bromine and iodine are preferred, and bromine and iodine are particularly preferred.

In a particularly preferred embodiment, Z¹ and Z² are selected, independently of one another, from Br, I and B(OR³)₂.

In a further embodiment of the present invention, the polymers according to the invention are not used as the pure substance, but instead as a mixture (blend) together with further polymeric, oligomeric, dendritic or low-molecular-weight substances of any desired type. These may, for example, improve the electronic properties or themselves emit. A “mixture” or “blend” above and below refers to a mixture comprising at least one polymeric component.

The present invention thus furthermore relates to a polymer mixture (blend) which comprises one or more polymers according to the invention, and one or more further polymeric, oligomeric, dendritic or low-molecular-weight substances.

The invention furthermore relates to solutions and formulations comprising one or more polymers or mixtures according to the invention in one or more solvents. The way in which solutions of this type can be prepared is known to the person skilled in the art and is described, for example, in WO 02/072714 A1, WO 03/019694 A2 and the literature cited therein.

These solutions can be used to produce thin polymer layers, for example by area-coating processes (for example spin coating) or by printing processes (for example ink-jet printing).

Polymers containing structural units of the formula (I) which contain one or more polymerisable, and thus crosslinkable, groups are particularly suitable for the production of films or coatings, in particular for the production of structured coatings, for example by thermal or light-induced in-situ polymerisation and in-situ crosslinking, such as, for example, in-situ UV photopolymerisation or photopatterning. For applications of this type, particular preference is given to polymers according to the invention containing one or more polymerisable groups selected from acrylate, methacrylate, vinyl, epoxy and oxetane. It is possible here not only to use corresponding polymers as the pure substance, but also to use formulations or blends of these polymers as described above. These can be used with or without addition of solvents and/or binders. Suitable materials, processes and devices for the methods described above are disclosed, for example, in WO 2005/083812 A2. Possible binders are, for example, polystyrene, polycarbonate, polyacrylate, polyvinylbutyral and similar, opto-electronically neutral polymers.

Suitable and preferred solvents are, for example, toluene, anisole, xylenes, methyl benzoate, dimethylanisoles, trimethylbenzenes, tetralin, dimethoxybenzenes, tetrahydrofuran, chlorobenzene and dichlorobenzene as well as mixtures thereof.

The polymers, mixtures and formulations according to the invention can be used in electronic or electro-optical devices or for the production thereof.

The present invention thus furthermore relates to the use of the polymers, mixtures and formulations according to the invention in electronic or electro-optical devices, preferably in organic or polymeric organic electroluminescent devices (OLED, PLED), organic field-effect transistors (OFETs), organic integrated circuits (O—ICs), organic thin-film transistors (TFTs), organic solar cells (O—SCs), organic laser diodes (O-lasers), organic photovoltaic (OPV) elements or devices or organic photoreceptors (OPCs), particularly preferably in organic or polymeric organic electroluminescent devices (OLED, PLED), in particular in polymeric electroluminescent devices (PLED).

The way in which OLEDs or PLEDs can be produced is known to the person skilled in the art and is described in detail, for example, as a general process in WO 2004/070772 A2, which should be adapted correspondingly for the individual case.

As described above, the polymers according to the invention are very particularly suitable as electroluminescent materials in PLEDs or displays produced in this way.

Electroluminescent materials in the sense of the present invention are taken to mean materials which can be used as active layer. Active layer means that the layer is capable of emitting light on application of an electric field (light-emitting layer) and/or that it improves the injection and/or transport of positive and/or negative charges (charge-injection or charge-transport layer).

The present invention therefore also preferably relates to the use of the polymers or blends according to the invention in a PLED, in particular as electroluminescent material.

The present invention furthermore relates to electronic or opto-electronic components, preferably organic or polymeric organic electroluminescent devices (OLED, PLED), organic field-effect transistors (OFETs), organic integrated circuits (O—ICs), organic thin-film transistors (TFTs), organic solar cells (O—SCs), organic laser diodes (O-lasers), organic photovoltaic (OPV) elements or devices or organic photoreceptors (OPCs), particularly preferably organic or polymeric organic electroluminescent devices, in particular polymeric organic electroluminescent devices, having one or more active layers, where at least one of these active layers comprises one or more polymers according to the invention. The active layer can be, for example, a light-emitting layer, a charge-transport layer and/or a charge-injection layer.

The present application text and also the examples below are principally directed to the use of the polymers according to the invention in relation to PLEDs and corresponding displays. In spite of this restriction of the description, it is possible for the person skilled in the art, without further inventive step, also to use the polymers according to the invention as semiconductors for the further uses described above in other electronic devices.

The following examples are intended to explain the invention without restricting it. In particular, the features, properties and advantages described therein of the defined compounds on which the relevant example is based can also be applied to other compounds which are not described in detail, but fall within the scope of protection of the claims, unless stated otherwise elsewhere.

### WORKING EXAMPLES

The following syntheses are carried out, unless indicated otherwise, under a protective-gas atmosphere in dried solvents. Starting material 1 and the solvents are commercially available. Compound 5 can be prepared analogously to J. Org. Chem., 2004, 69, 6766-6771. Compounds 8 and 10 can be prepared analogously to Eur. J. Inorg. Chem., 2007, 3, 372-375.

### Examples 1 and 2

### Preparation of monomers M1 and M2

### Example 1

### Preparation of Compound 9 (M1)

Compound 9 is prepared as follows:

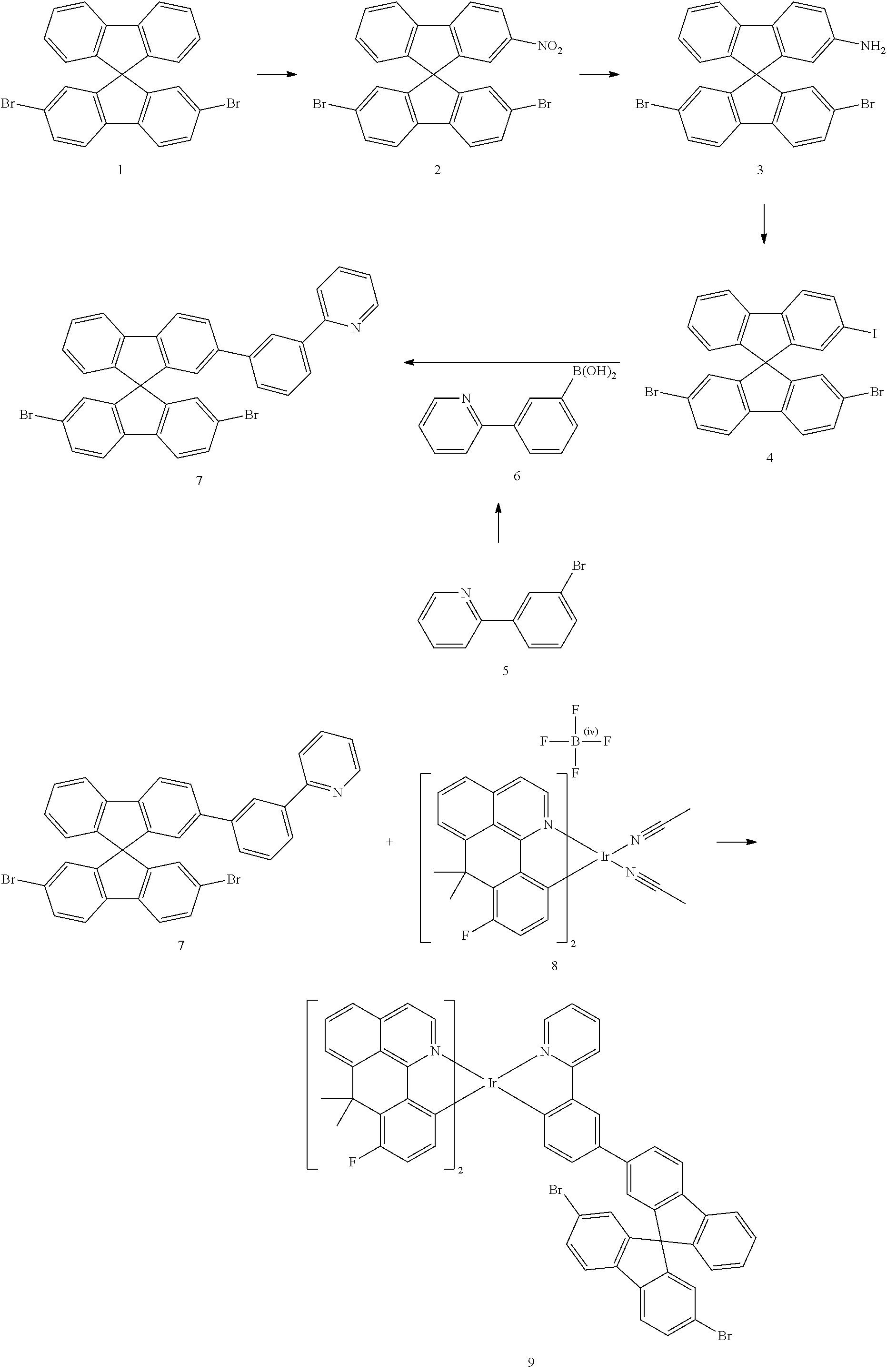

### 1.1 Compound 2

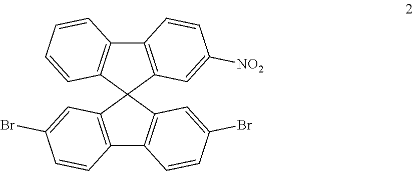 [SMILES: O=[N+]([O-])c1ccc2c(c1)C1(c3ccccc3-2)c2cc(Br)ccc2-c2ccc(Br)cc21]

100.0 g (0.2 mol) of compound 1 are initially introduced in 500 ml of nitrobenzene. 35 ml (0.8 mol) of nitric acid in 90 ml of glacial acetic acid are added dropwise at room temperature, the mixture is subsequently stirred at −70° C. for a further 3 hours. The reaction mixture is then poured into 1250 ml of water and 2500 ml of ethanol. The precipitated solid is filtered off with suction, washed in ethanol and employed in the subsequent reaction without further purification. The yield is 98.0 g (0.19 mol, 90%).

### 1.2 Compound 3

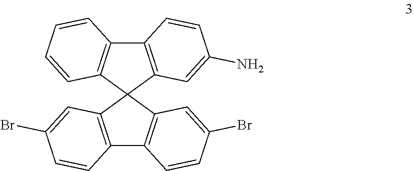 [SMILES: Nc1ccc2c(c1)C1(c3ccccc3-2)c2cc(Br)ccc2-c2ccc(Br)cc21]

32.6 g (62.8 mmol) of compound 2 are initially introduced in 650 ml of methanol, and 1.3 g of palladium on active carbon is added. The reaction mixture is cooled to 0° C., and 5.2 g (138.5 mmol) of NaBH₄ is added in portions. The reaction solution is stirred overnight at room temperature. When the reaction is complete, 400 ml of water is carefully added. The phases are separated, and the aqueous phase is extracted with DCM (dichloromethane). The organic phases are combined, dried over sodium sulfate, and evaporated under reduced pressure. The yellow residue is washed in methanol and employed in the subsequent reaction without further purification. The yield is 23.9 g (48 mol, 78%).

### 1.3 Compound 4

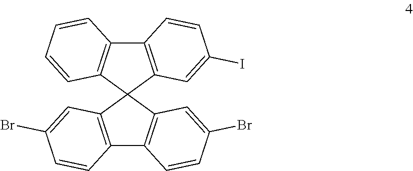 [SMILES: Brc1ccc2c(c1)C1(c3ccccc3-c3ccc(I)cc31)c1cc(Br)ccc1-2]

500 ml of conc. HCl and 750 ml of water are added to 53 g (0.11 mol) of compound 3. The reaction mixture is cooled to 0° C. 8.2 g (0.12 mol) of sodium nitrite dissolved in 25 ml of water are added dropwise at such a rate that the internal temperature does not exceed 1° C. After 30 minutes, 36.0 g (0.22 mol) of potassium iodide dissolved in 40 ml of water are slowly added dropwise. The reaction mixture is stirred overnight at room temperature. The precipitated solid is filtered off with suction, dissolved in dichloromethane, washed with a 2N Na₂SO₃ solution, dried over Na₂SO₄ and evaporated under reduced pressure. The residue is recrystallised from toluene. The yield is 24.0 g (0.04 mol, 37%).

### 1.4 Compound 6

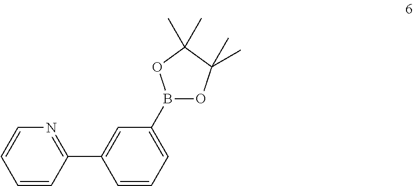 [SMILES: CC1(C)OB(c2cccc(-c3ccccn3)c2)OC1(C)C]

1300 ml of dioxane, 114.8 g (1.10 mol) of bis(pinacolato)diborane and 121.23 g (1.23 mol) of potassium acetate are added to 96.3 g (0.41 mol) of 2-(3-bromophenyl)pyridine 5. 16.83 g (0.02 mmol) of 1,1-bis(diphenylphosphine)ferrocenepalladium(II) chloride (complex with dichloromethane (1:1), Pd: 13%) are subsequently added. The batch is heated to 110° C. After a TLC check, the batch is cooled to room temperature, and 200 ml of water are added. A further 50 ml of water are subsequently added for phase separation. The mixture is extracted with ethyl acetate, the combined organic phases are then dried over sodium sulfate, filtered and evaporated under reduced pressure. The residue is recrystallised from heptane/toluene. The yield is 55.1 g (0.2 mol, 48%).

### 1.5 Compound 7

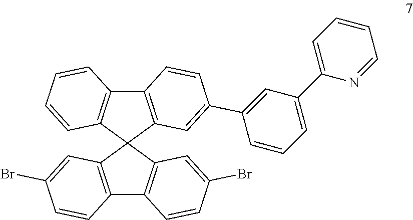 [SMILES: Brc1ccc2c(c1)C1(c3ccccc3-c3ccc(-c4cccc(-c5ccccn5)c4)cc31)c1cc(Br)ccc1-2]

320 ml of toluene and 280 ml of water are added to 17.4 g (0.03 mol) of compound 4, 8.15 g (0.03 mol) of compound 6 and 20.6 g (0.14 mmol) of potassium carbonate. The batch is saturated with N₂, and 168 mg (0.145 mmol) of Pd(Ph₃)₄ are added. The batch is stirred under reflux for 24 hours. After cooling to room temperature, the reaction mixture is extracted with toluene. The organic phase is washed with water, dried over Na₂SO₄ and evaporated under reduced pressure. The residue is recrystallised from acetonitrile/toluene. The yield is 7.82 g (0.01 mol, 43%).

### 1.6 Compound 9

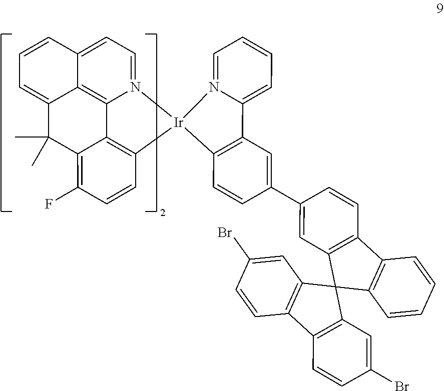

25 ml of 2-ethoxyethanol are added to 0.38 g (0.43 mmol) of compound 8 and 0.54 g (0.86 mmol) of compound 7 under protective gas. The reaction mixture is heated to 115° C. and stirred at this temperature for 4 days. After cooling to room temperature, 45 ml of a mixture of methanol and water (10/1) are added to the batch. The precipitated solid is filtered off with suction and washed with methanol. The product is purified by means of column chromatography (silica gel; eluent: toluene/heptane 6/4). The yield is 0.13 g (0.10 mol, 23%).

### Example 2

### Preparation of Compound 11 (M2)

Compound 11 is prepared as follows:

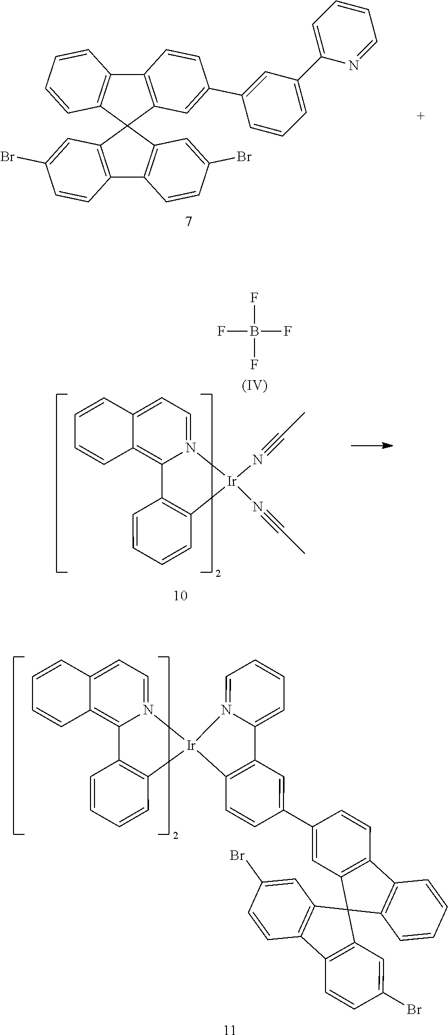

### 2.1 Compound 11

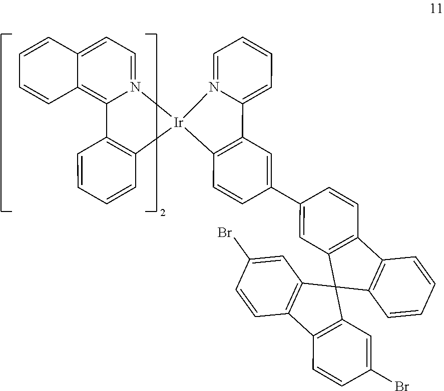

50 ml of 2-ethoxyethanol are added to 0.61 g (0.80 mmol) of compound 10 and 1.0 g (1.59 mmol) of compound 7 under protective gas. The reaction mixture is heated to 115° C. and stirred at this temperature for 4 days. After cooling to room temperature, 100 ml of a mixture of methanol and water (10/1) are added to the batch. The precipitated solid is filtered off with suction and washed with methanol. The product is purified by means of column chromatography (silica gel; eluent: toluene/heptane 6/4). The yield is 0.48 g (0.39 mmol, 48%).

### Examples 3 to 5

### Preparation of the Polymers

Polymers P1 and P2 according to the invention and comparative polymer V1 are synthesised by SUZUKI coupling in accordance with WO 03/048225 A2 using the following monomers (percent data=mol %).

### Example 3

### Polymer P1

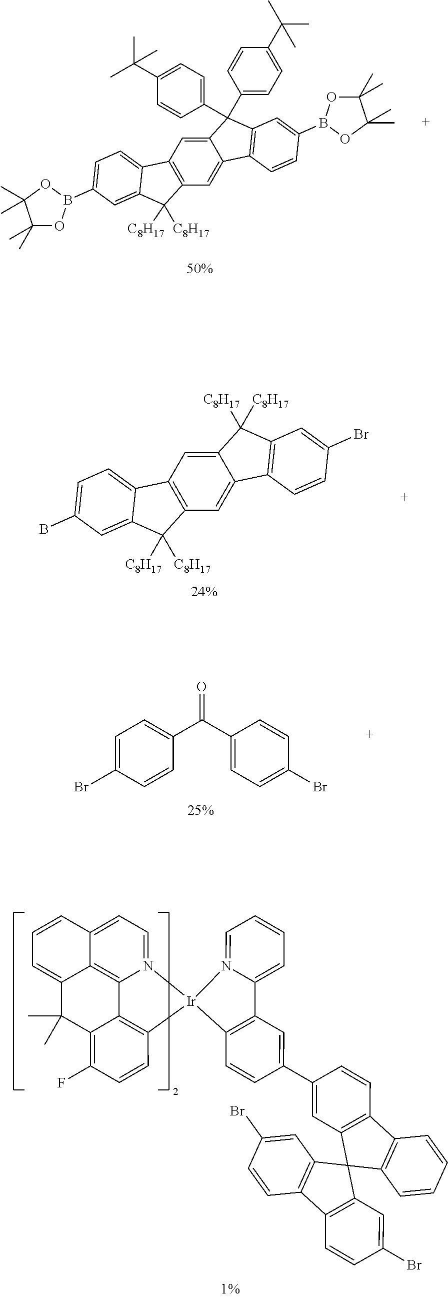

### Example 4

### Polymer P2

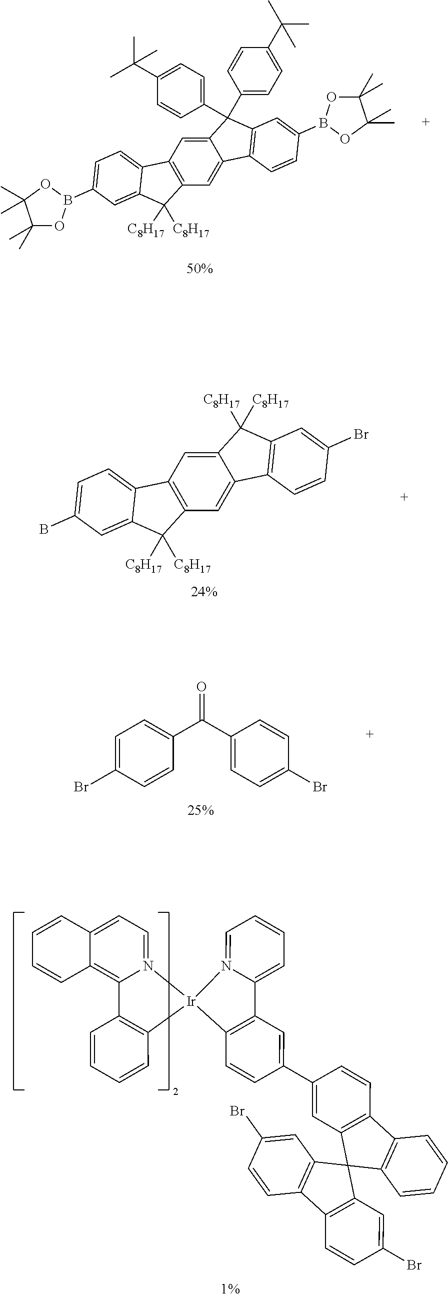

### Comparative Example 5

### Polymer V1

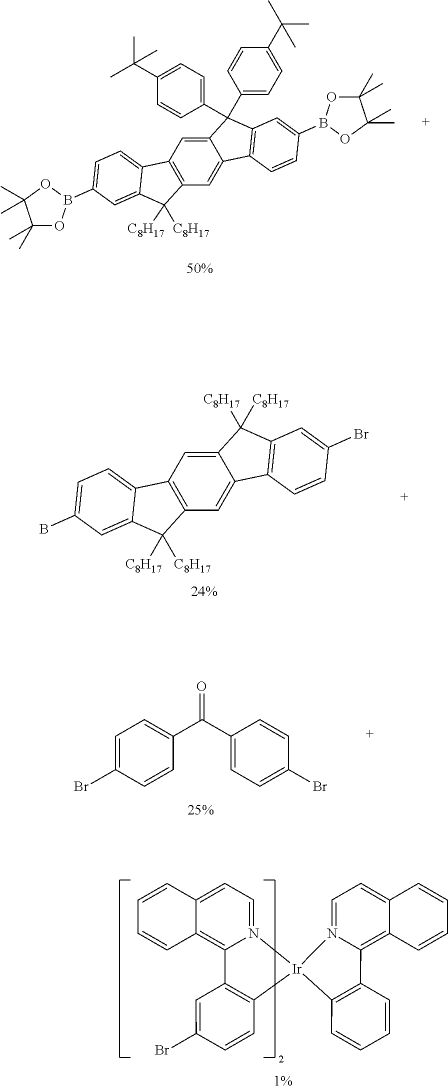

### Examples 6 to 8: Production of PLEDs

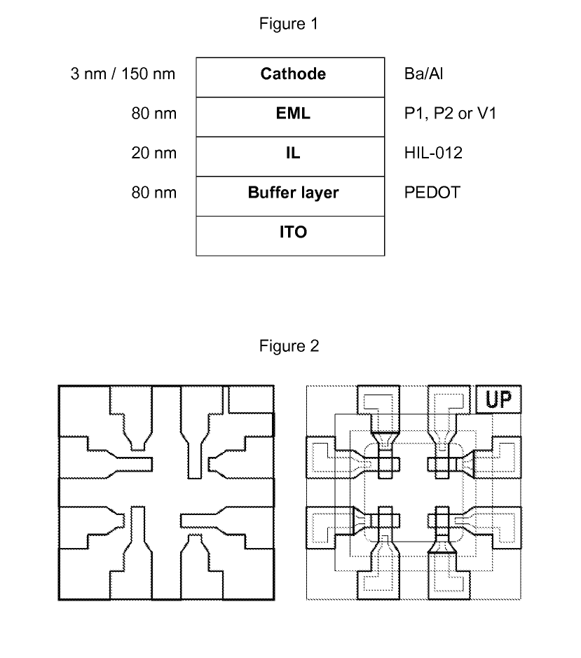

The production of a polymeric light-emitting (PLED) has already been described many times in the literature (for example in WO 2004/037887 A2). In order to explain the present invention by way of example, PLEDs comprising polymers P1 and P2 and comparative polymer V1 are produced by spin coating. A typical device has the structure depicted in FIG. 1.

To this end, specially manufactured substrates from Technoprint are used in a layout designed specifically for this purpose (FIG. 2, diagram on the left: ITO structure applied to the glass support, diagram on the right: complete electronic structure with ITO, vapour-deposited cathode and optional metallisation of the leads). The ITO structure (indium tin oxide, a transparent, conductive anode) is applied to soda-lime glass by sputtering in a pattern such that 4 pixels measuring 2×2 mm are obtained with the cathode vapour-deposited at the end of the production process.

The substrates are cleaned with deionised water and a detergent (Deconex 15 PF) in a clean room and then activated by UV/ozone plasma treatment. An 80 nm layer of PEDOT (PEDOT is a polythiophene derivative (Baytron P VAI 4083sp.) from H. C. Starck, Goslar, which is supplied as an aqueous dispersion) is then applied by spin coating, likewise in the clean room. The spin rate required depends on the degree of dilution and the specific spin-coater geometry (typical for 80 nm: 4500 rpm). In order to remove residual water from the layer, the substrates are dried by heating on a hotplate at 180° C. for 10 minutes. Then, under an inert-gas atmosphere (nitrogen or argon), firstly 20 nm of an interlayer (typically a holedominated polymer, here HIL-012 from Merck) and then 80 nm of the polymer layers are applied from toluene solutions (interlayer concentration 5 WI, for polymers P1, P2 and V1 between 8 and 10 g/l). The two layers are dried by heating at 180° C. for at least 10 minutes. The Ba/Al cathode is then vapour-deposited in the pattern indicated through a vapour-deposition mask (high-purity metals from Aldrich, particularly barium 99.99% (Order No. 474711); vapour-deposition units from Lesker or others, typical vacuum level 5×10⁻⁶ mbar). In order, in particular, to protect the cathode against air and atmospheric moisture, the device is finally encapsulated and then characterised.

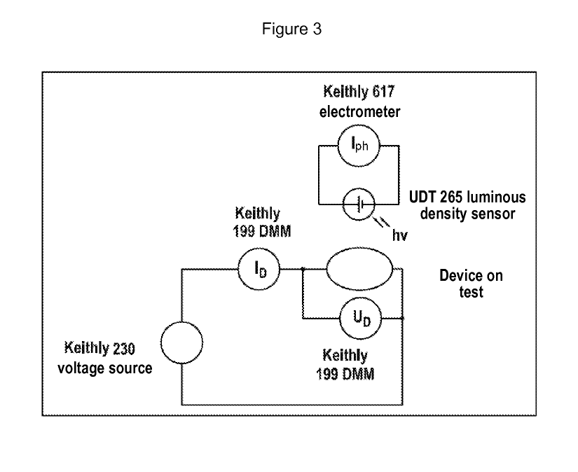

To this end, the devices are clamped into holders manufactured specifically for the substrate size and provided with spring contacts. A photodiode with eye response filter can be placed directly on the measurement holder in order to exclude influences from extraneous light. The typical measurement set-up is depicted in FIG. 3.

The voltages are typically increased from 0 to max. 20 V in 0.2 V steps and reduced again. For each measurement point, the current through the device and the photocurrent obtained is measured by the photodiode. In this way, the IVL data of the test devices are obtained. Important parameters are the maximum efficiency measured (“max. eff.” in cd/A) and the voltage required for 100 cd/m².

In order, in addition, to know the colour and the precise electroluminescence spectrum of the test devices, the voltage required for 100 cd/m² is applied again after the first measurement, and the photodiode is replaced by a spectrum measuring head. This is connected to a spectrometer (Ocean Optics) by an optical fibre. The colour coordinates (CIE: Commission Internationale de I′Eclairage, standard observer from 1931) can be derived from the measured spectrum.

The solution-processed devices are characterised by standard methods, the OLED examples given are not optimised.

The results obtained on use of polymers P1 and P2 as well as V1 in PLEDs are summarised in Table 1.

TABLE 1
Results in the device configuration of FIG. 1

| | | | U @ | | |
|---|---|---|---|---|---|
| | | Max. eff. | 100 cd/m² | Lifetime | CIE |
| Ex. | Polymer | [cd/A] | [V] | @1000 cd/m² [h] | [x/y] |
| 6 | V1 | 3.3 | 7.5 | 3500 | 0.68/0.32 |
| 7 | P1 | 13.4 | 4.5 | 13500 | 0.63/0.37 |
| 8 | P2 | 15.2 | 4.4 | 12000 | 0.65/0.35 |

As can be seen from the results, polymers P1 and P2 according to the invention represent a significant improvement over the comparable polymer in accordance with the prior art with respect to operating voltage, efficiency and lifetime.

1-12. (canceled)

13. A polymer which comprises at least one structural unit of the following formula (I): 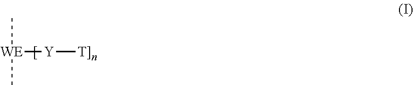
where the symbols and indices used have the following meanings:
WE represents the recurring unit in the polymer;
Y represents a single covalent bond or a conjugation-interrupting unit;
T is a phosphorescent emitter unit;
n is 1, 2, 3 or 4;
and the dashed lines represent the linking in the polymer.

14. The polymer according to claim 13, wherein the phosphorescent emitter unit T contains a metal-ligand coordination compound.

15. The polymer according to claim 14, wherein the metal-ligand coordination compound contains at least one bi- or polydentate organic ligand.

16. The polymer according to claim 14, wherein the metal in the at least one metal-ligand coordination compound is Pt or Ir.

17. The polymer according to claim 13, wherein the proportion of the structural units of the formula (I) is 0.01 to 50 mol %, based on the total number of structural units of the polymer.

18. A process for the preparation of the polymer according to claim 13, which comprises preparing the polymer by SUZUKI, YAMAMOTO, STILLE or HARTWIG-BUCHWALD polymerisation.

19. A compound of the following formula (II) 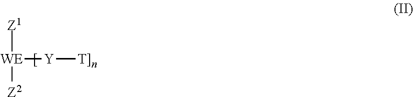
where the symbols and indices used have the following meanings:
Z¹ and Z² are, independently of one another, a halogen, O-tosylate,
O-triflate, O—SO₂R³, B(OR³)₂ or Sn(R³)₃;
R³ is selected on each occurrence, independently of one another, from the group consisting of hydrogen, an aliphatic hydrocarbon radical having 1 to 20 C atoms and an aromatic hydrocarbon radical having 1 to 20 C atoms, where two or more radicals R³ may form a ring system with one another
WE represents the recurring unit in the polymer;
Y represents a single covalent bond or a conjugation-interrupting unit;
T is a phosphorescent emitter unit; and
n is 1, 2, 3 or 4.

20. A mixture which comprises one or more polymer(s) according to claim 13 and further polymeric, oligomeric, dendritic and/or low-molecular-weight substances.

21. A solution or formulation comprising one or more polymer(s) according to claim 13 in one or more solvents.

22. A solution or formulation comprising the mixture according to claim 20 in one or more solvents.

23. An electronic device which comprises the polymer according to claim 13.

24. An electronic device which comprises the mixture according to claim 20 or a solution according to claim 21.

25. The electronic device as claimed in claim 23, wherein the device is an organic electroluminescent device.

26. An organic electronic device which comprises one or more active layers wherein at least one of these active layers comprises one or more polymer(s) according to claim 13.

27. An organic electronic device which comprises one or more active layers wherein at least one of these active layers comprises the mixture according to claim 20.

28. The organic electronic device according to claim 26, wherein the device is an organic or polymeric organic electroluminescent device (OLED, PLED), an organic integrated circuit (O—IC), an organic field-effect transistor (OFET), an organic thin-film transistor (OTFT), an organic solar cell (O—SC), an organic laser diode (O-laser), an organic photovoltaic (OPV) element or device or an organic photoreceptor (OPCs).

29. The organic electronic device according to claim 26, wherein the device is a polymeric organic electroluminescent device (PLED).
